(19) United States
(12) Patent Application Publication
(10) Pub. No.: US 2023/0332839 A1
(43) Pub. Date: Oct. 19, 2023

(54) VAPOR CHAMBERS FEATURING WETTABILITY-PATTERNED SURFACES

(71) Applicant: THE BOARD OF TRUSTEES OF THE UNIVERSITY OF ILLINOIS, Urbana, IL (US)

(72) Inventors: Constantine M. MEGARIDIS, Chicago, IL (US); Georg DAMOULAKIS, Chicago, IL (US); Theodore P. KOUKORAVAS, Chicago, IL (US)

(21) Appl. No.: 18/027,852

(22) PCT Filed: Sep. 22, 2021
(86) PCT No.: PCT/US2021/051602

§ 371 Date: Mar. 22, 2023

Related U.S. Application Data
(60) Provisional application No. 63/197,173, filed on Jun. 4, 2021.
(60) Provisional application No. 63/194,094, filed on May 27, 2021.
(60) Provisional application No. 63/082,250, filed on Sep. 23, 2020.

(51) Int. Cl. F28D 15/04

(52) U.S. Cl. CPC F28D 15/04

(57) ABSTRACT

Wick-free vapor chambers and hybrid vapor chambers are described. An example wick-free vapor chamber includes a wettability-patterned condenser configured to control vapor condensation along patterned domains formed on the wettability-patterned condenser; and a wettability-patterned evaporator. The wettability patterned evaporator is configured to: i) accept condensate from the wettability-patterned condenser and ii) transport the condensate along patterned domains formed on the wettability-patterned evaporator to one or more hot domain portions of the wettability-patterned evaporator. An example hybrid vapor chamber includes a wettability patterned condenser configured to control vapor condensation along patterned domains formed on the wettability-patterned condenser; and an evaporator configured to accept condensate from the wettability -patterned condenser.

### RELATED APPLICATIONS

This application claims priority to the following U.S. Provisional Patent Applications, each of which is herein incorporated by reference in its entirety: U.S. Provisional Patent Application No. 63/082,250 filed Sep. 23, 2020, entitled Vapor Chamber/Heat Spreader With Wickless Wettability-Patterned Condenser and Related Applications; U.S. Provisional Patent Application No. 63/194,094 filed May 27, 2021, entitled Vapor Chamber/Heat Spreader With Wickless Wettability-Patterned Condenser and Related Applications; and U.S. Provisional Patent Application No. 63/197,173 filed Jun. 4, 2021, entitled Vapor Chamber/Heat Spreader With Wickless Wettability-Patterned Condenser and Related Applications.

### STATEMENT OF U.S. GOVERNMENT INTEREST

This invention was made with government support under FA4600-12-D-9000-17-FU909 awarded by the Office of Naval Research and N00014-20-1-2025 awarded by the Office of Naval Research. The government has certain rights in the invention.

### FIELD OF THE INVENTION

The disclosure herein relates generally to heat transfer and thermal management, and in particular, to vapor chambers that facilitate heat transfer encountered in thermal management.

### BACKGROUND

Heat-flow control research attracts considerable interest from academia and industry, especially in the field of thermal management of electronics. The combination of the continuous reduction in electronics size with ever increasing power output is pushing the limits of heat-dissipation technologies. Heat spreading devices, such as vapor chambers, offer a solution to this problem and can dissipate heat more effectively than solid-metal heat sinks.

Vapor chambers are hermetically sealed, hollow devices that carry a phase-changing liquid to attain a high effective thermal conductivity (low thermal resistance) produced by the spreading of vapor generated via thin-film evaporation or even boiling of the liquid in contact with the hot side of the device (evaporator). The vapor created in this manner condenses on the cooled side of the device and the condensate travels back to the evaporator through capillary action to restart the phase-change cycle.

Conventional vapor-chambers include copper-wick-lined interior walls, and can utilize a multitude of liquids, such as water, acetone or ethanol, to reach device thermal resistances as low as 0.1 K/W, depending on the positioning of the device. Hybrid designs have also been developed, as for example when Boreyko and Chen combined traditional wick structures on the evaporator with a functionalized superhydrophobic condenser surface, to obtain a heat transfer coefficient of the order of 10 kW/m²K. Shaeri et al. approached the reverse problem with a hydrophobic evaporator and a wick-lined condenser, and reported a thermal resistance of ˜0.35 K/W. Silicon-wafer based vapor chambers have also been developed and displayed thermal resistance as low as ˜0.25 K/W. Besides the published experimental work, researchers have also attempted to analytically examine vapor chambers using both simplified models and sophisticated CFD-type analysis.

Some vapor chambers take advantage of capillarity by utilizing wicks to pumplessly move the condensed fluid around the device interior. However, the small pore size required to achieve rapid transport gives rise to high viscous losses, with subsequent high pressure drops which degrade performance. This not only limits transport speeds, but transport distances as well. So, as the heat flux passing through a vapor chamber increases, the fluid mass flow rate circulating inside the chamber has to increase accordingly in order to prevent dryout over the heated domain that can lead to thermal runaway. When viscous losses rise to the point of surpassing capillary pressure, the device is in danger of thermal runaway. This defines the capillary limit in those devices, where the wick dimensions and properties (pore size, material, etc.) are the limiting factor for increasing the maximum heat flux that the device can handle before it reaches thermal runaway, with potentially catastrophic consequences.

Improvements are therefore desired.

### SUMMARY

In one example aspect, a wick-free vapor chamber is provided. The wick-free vapor chamber includes a wettability-patterned condenser configured to control vapor condensation along patterned domains formed on the wettability-patterned condenser. The wick-free vapor chamber also includes a wettability-patterned evaporator configured to: i) accept condensate from the wettability-patterned condenser and ii) transport the condensate along patterned domains formed on the wettability-patterned evaporator to a hot domain portion of the wettability-patterned evaporator.

In another example aspect, a system including a heat source and a wick-free vapor chamber is provided. The wick-free vapor chamber is operably connected to the heat source and includes a wettability-patterned condenser and a wettability-patterned evaporator. The wettability-patterned condenser is configured to control vapor condensation along patterned domains formed on the wettability-patterned condenser. The wettability-patterned evaporator is configured to: i) accept condensate from the wettability-patterned condenser and ii) transport the condensate along patterned domains formed on the wettability-patterned evaporator to a hot domain portion of the wettability-patterned evaporator.

In another example aspect, a method is provided. The method includes: i) forming a condenser wettability pattern on a surface of a first plate; ii) forming an evaporator wettability pattern on a surface of a second plate; iii) joining the first plate and the second plate in parallel so as to form a wick-free vapor chamber; iv) evacuating a vapor space between the surface of the first plate and the surface of the second plate using a vacuum pump; and v) supplying a phase-changing liquid to the vapor space.

In another example aspect, a wettability-patterned evaporator for a wick-free vapor chamber is provided. The wettability-patterned evaporator includes patterned domains formed on the wettability-patterned evaporator and configured to: i) accept condensate from a wettability-patterned condenser and ii) transport the condensate along the patterned domains to a hot domain portion of the wettability-patterned evaporator.

In another example aspect, a vapor chamber is provided. The vapor chamber includes a wettability-patterned condenser and an evaporator. The wettability-patterned condenser is configured to control vapor condensation along patterned domains formed on the wettability-patterned condenser. The evaporator is configured to accept condensate from the wettability-patterned condenser.

In another example aspect, a system including a heat source and a vapor chamber is provided. The vapor chamber is operably connected to the heat source and includes a wettability-patterned condenser and an evaporator. The wettability-patterned condenser is configured to control vapor condensation along patterned domains formed on the wettability-patterned condenser. The evaporator is configured to accept condensate from the wettability-patterned condenser.

In another example aspect, a method is provided. The method includes: i) forming a condenser wettability pattern on a first plate; ii) joining the first plate and a second plate in parallel so as to form a vapor chamber; iii) evacuating a vapor space between the surface of the first plate and the second plate using a vacuum pump; and iv) supplying a phase-changing liquid to the vapor space

These as well as other aspects, advantages, and alternatives, will become apparent to those of ordinary skill in the art by reading the following detailed description, with reference where appropriate to the accompanying drawings.

### BRIEF DESCRIPTION OF THE FIGURES

FIG. 1 is a cross-sectional view of an example of a hybrid vapor chamber with wicking posts.

FIG. 2 is a top view of the vapor chamber of FIG. 1.

FIG. 3 illustrates example condenser wettability patterns.

FIG. 4 shows the surface profile of an example wettability-patterned condenser.

FIG. 5 illustrates a cross-sectional view of another example of a hybrid vapor chamber without wicking posts.

FIG. 6 shows experimental results for a control device.

FIGS. 7-10 shows experimental results for example hybrid vapor chambers.

FIG. 11 shows pathways along which heat generated from a heater can spread inside an experimental setup.

FIGS. 12 and 13 show additional experimental results for example hybrid vapor chambers—thermal diodes.

FIG. 14 illustrates the working principles of an example diode in a forward mode and a reverse mode.

FIG. 15 illustrates the diodic behavior of an example hybrid vapor chamber.

FIG. 16 illustrates an example wick-free vapor chamber.

FIG. 17 depicts another example wick-free vapor chamber.

FIG. 18 illustrates an example combination of wettability patterns.

FIG. 19 illustrates the working principle of an example wick-free vapor chamber.

FIGS. 20 and 21 illustrate additional example wettability patterns.

FIG. 22 illustrates an example wettability-patterned evaporator.

FIG. 23 illustrates the performance of various wick-free vapor chambers.

FIG. 24 plots the thermal performance of an example wick-free vapor chamber—thermal diode.

FIG. 25 is a flow chart of an example method for creating a hybrid vapor chamber.

FIG. 26 is a flow chart of another example method for creating a wick-free vapor chamber.

### DETAILED DESCRIPTION

### I. Overview

As noted above, some vapor chambers take advantage of capillarity by utilizing wicks to pumplessly move the condensed fluid around the device interior. The wick dimensions and properties (pore size, material, etc.) are limiting factors for increasing the maximum heat flux that the device can handle before reaching thermal runaway. Described herein are vapor chambers that replace the wick on the condenser side of the device with wettability patterning, so that the risk for dryout can be partially mitigated.

As used herein, wettability patterning refers to modification of a surface to include a pattern combining wettable domains and non-wettable domains. The wettability of a material is dependent on both its physical and chemical characteristics. If a liquid spreads completely across the surface of a material and forms a film, the contact angle is close to 0 degrees (°). Such a surface may be said to be superhydrophilic. If the liquid beads on the surface, the surface is considered to be non-wettable by this specific liquid. For water, the substrate surface is considered to be hydrophobic if the contact angle is greater than 90°. Certain applications may require a hydrophobic coating with a high contact angle of at least 150°. These coatings may be said to be superhydrophobic.

An example vapor chamber can include a wettability-patterned condenser that is configured to control vapor condensation along patterned domains formed on the wettability-patterned condenser, and an evaporator that is configured to accept condensate from the wettability-patterned condenser. The wettability-patterned condenser includes a pattern of wettable domains that promote filmwise condensation and non-wettable domains that promote dropwise condensation. The patterned domains of the wettability-patterned condenser are configured to collect the condensate at collection domains (e.g., circular end-wells), and return the condensate from the collection domains to the evaporator. The evaporator can include an evaporator wick. Optionally, the evaporator can include wicking posts that contact the condensate collection domains of the wettability-patterned condenser.

Advantageously, the use of wettability patterning increases condensation performance as compared to condensation on a homogenous surface. Condensation heat transfer occurs in two primary modes, dropwise condensation (DWC) and filmwise condensation (FWC), the former offering an order of magnitude higher heat transfer coefficient (HTC) than the latter. The overall performance of DWC depends on several factors, such as droplet nucleation density and rate, maximum size of departing droplets and rapid condensate drainage. Wettability patterning is capable of controlling the above three factors (i.e., achieving spatial nucleation, decreasing the departing droplet size and facilitating rapid drainage of condensate).

In addition, the use of wettability patterning on the condenser side of the vapor chamber allows for rapid, pumpless transport of condensate back to the evaporator side of the vapor chamber, thereby increasing the efficiency of the phase-change cycle. For instance, the use of wettability patterning allows for transporting fluids on an open planar surface using interfacial forces, which results in lower viscous losses, higher transport speeds, and longer transport distances, as compared to those attained in porous materials. These characteristics of wettability patterning allow vapor chambers utilizing wettability patterning to exhibit lower thermal resistances on the condensation side and, in turn, lower device total thermal resistances.

Moreover, wettability-patterned condenser plates can allow for strategically-placed water collection domains (e.g., end-wells) which can replace wicking posts usually deployed in vapor chambers. Hence, the use of wettability-patterned condensers can simplify the fabrication and assembly of vapor chambers.

Another example vapor chamber includes a wettability-patterned condenser as well as a wettability-patterned evaporator. The wettability-patterned condenser is configured to control vapor condensation along patterned tacks formed on the wettability-patterned condenser. The wettability-patterned evaporator, in turn, is configured to: i) accept condensate from the wettability-patterned condenser and ii) transport the condensate along patterned domains formed on the wettability-patterned evaporator to a hot domain portion of the wettability-patterned evaporator, where the condensate can then evaporate and cool the area locally.

Utilizing wettability patterning on both the condenser side and the evaporator side of the vapor chamber allows for a wick-free vapor chamber. A wick-free vapor chamber can be constructed by simply modifying surfaces of the condenser and the evaporator instead of fabricating wicks using volumetric processes (e.g., sintering). As such, manufacturing a wick-free vapor chamber may be less complex, faster, and more cost-effective than manufacturing a vapor chamber having wicks.

Various other features and variations of the vapor chambers, as well as corresponding systems and methods, are described hereinafter with reference to the accompanying figures.

### II. Example Hybrid Vapor Chambers

In line with the discussion above, wettability patterning is useful for increasing the performance of a vapor chamber. For instance, the use of wettability patterning on a condenser of a vapor chamber can lower the device total thermal resistance of a vapor chamber. As used herein, a vapor chamber having a wettability-patterned side and a wick-lined side is referred to as a hybrid vapor chamber.

### A. Hybrid Vapor Chamber With Wicking Posts

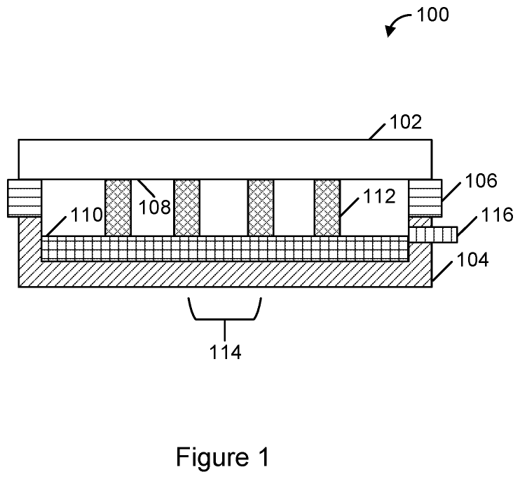

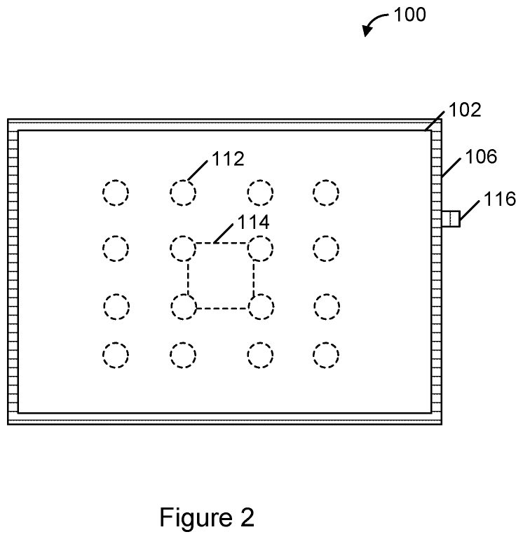

FIGS. 1 and 2 illustrate an example vapor chamber 100. In particular, FIG. 1 is a cross-sectional side view of vapor chamber 100, and FIG. 2 is a top view of vapor chamber 100. As shown in FIGS. 1 and 2, vapor chamber 100 includes a wettability-patterned condenser 102, an evaporator 104, and a spacer (gasket) 106. Wettability-patterned condenser 102 and evaporator 104 are distinct parts of vapor chamber 100. Each of wettability-patterned condenser 102 and evaporator 104 are rectangular in shape. For instance, wettability-patterned condenser 102 and evaporator 104 can include copper plates. Alternatively, wettability-patterned condenser 102 and evaporator 104 can include plates made of other metals and/or metal alloys.

When vapor chamber 100 is assembled, spacer 106 forms a vapor space between wettability-patterned condenser 102 and evaporator 104. Spacer 106 can include a rubber gasket, for instance, that facilitates sealing vapor chamber 100. Use of spacer 106 facilitates rapid replacement of evaporator 104 or wettability-patterned condenser 102. However, the presence of spacer 106 is not necessary. Rather than using spacer 106, wettability-patterned condenser 102 can be joined directly to evaporator 104.

For instance, in some vapor chambers, wettability-patterned condenser 102 can include raised edges that are configured to mate with the edges of evaporator 104, forming sides of the vapor chamber and defining the vapor space between wettability-patterned condenser 102 and evaporator 104. Additionally or alternatively, evaporator 104 can include raised edges that are configured to mate with the edges of wettability-patterned condenser 102.

Wettability-patterned condenser 102 is configured to control condensation along patterned domains formed on a surface 108 of wettability-patterned condenser. Surface 108 of wettability-patterned condenser 102 includes a pattern of wettable domains that promote filmwise condensation and non-wettable domains that promote dropwise condensation (not shown in FIGS. 1 and 2). By way of example, the patterned domains on surface 108 can include wettable tracks that are configured to collect condensate at collection domains and return the condensate from the collection domains to evaporator 104. The collection domains can include superhydrophilic areas for bridging the condensate to evaporator 104. For instance, the collection domains can include circular end-wells. The non-wettable domains on surface 108 can include hydrophobic areas that divide the patterned domains of wettability-patterned condenser 102 into separate superhydrophilic areas having respective collection domains.

As further shown in FIG. 1, evaporator 104 houses an evaporator wick 110 and wicking posts 112. Wicking posts 112 reach collection domains on surface 108 of wettability-patterned condenser 102. With this arrangement, wicking posts 112 facilitate bridging condensate accumulated at collection domains of surface 108 to evaporator wick 110. Evaporator 104 includes sixteen wicking posts in this example. In other examples, an evaporator may include more or fewer wicking posts. Optionally, the number of wicking posts may coincide with the number of collection domains on the wettability-patterned condenser.

Evaporator wick 110 includes a hot domain portion 114 that is configured to accumulate the condensate. As shown in FIG. 2, for this example, hot domain portion 114 is a rectangular region near a center of evaporator 104. In other examples, hot domain portion 114 can be located in other positions or have a different shape. Hot domain portion 114 can be positioned adjacent to a heat source, such that the heat vaporizes the condensate accumulated at hot domain portion 114. In some instances, hot domain portion 114 can include multiple hot domain portions, with each hot domain portion configured to contact a respective heat source of a system (an electrical circuit, for example). The size and shape of hot domain portion 114 may vary based on the size and shape of the heat source that hot domain portion 114 is intended to overlay.

Vapor chamber 100 also includes a tube 116. Tube 116 is inserted within a through-hole in evaporator 104. Tube 116 is usable to evacuate vapor chamber 100 (e.g., using a vacuum pump) and to supply a liquid to the vapor space formed between wettability-patterned condenser 102, evaporator 104, and spacer 106. The liquid can vary depending on the desired implementation. Generally, the liquid can include any phase-changing liquid. For instance, the liquid can include water, ethylene glycol, a hydrocarbon, an oil, ammonia, a solvent, alcohol, a refrigerant, or a dielectric fluid.

The dimensions of vapor chamber 100 can vary depending on the desired implementation. For instance, the lateral extent of vapor chamber 100 can vary from a few millimeters (e.g. 50 mm×50 mm) to a few meters (e.g., 1 m×2 m). The interspacing between surface 108 of wettability-patterned condenser 102 and evaporator wick 110 can vary from a fraction of a millimeter (e.g., 0.5 mm) to approximately one centimeter.

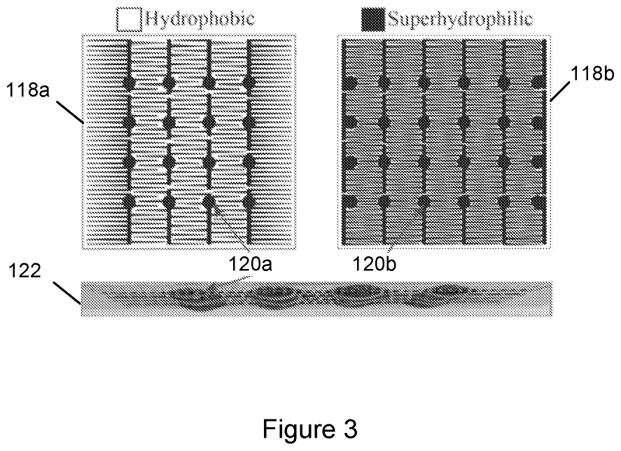

FIG. 3 illustrates an example wettability pattern 118a and an example wettability-pattern 118b. Wettability pattern 118a and wettability pattern 118b are two examples of wettability patterns that can be provided on a condenser, such as wettability-patterned condenser 102 of FIGS. 1 and 2. The designs of wettability pattern 118a and 118b feature interdigitated wettable domains (shown in black) and non-wettable domains (shown in white). The wettable domains include diverging tracks positioned next to each other, feeding into central stems of constant width. The diverging tracks have a starting width of 0.2 mm, a two-degree wedge angle, and lengths that vary up to 10 mm depending on position within the design. The central stems are 1 mm×48.8 mm, allowing for a 1 mm clearance on each side of the 50.8 mm active condenser plate area.

Wettability pattern 118a includes end-wells 120a. Similarly, wettability pattern 118b includes end-wells 120b. End-wells 120a and end-wells 120b act as condensate accumulation regions. The condensate accumulates in these end wells that have large enough radii of curvature, so that the Laplace pressure in these pools is small. This, in turn, facilitates the condensate transport form the tracks to the end-wells. The central stems of the end-wells are not continuous. Rather, small hydrophobic gaps with a width that depended on the overall spacing of the tracks for each design exist in between each end-well region in order to divide the superhydrophilic areas into parts/circuits that included only a single end-well. This distribution strategy ensures that the condensate from every location gets transported to a specific end-well, without having a lowest-pressure competition among end-wells, which would be the case if more than one end-well were part of the same superhydrophilic condensate circuit.

Wettability pattern 118a is designed to work in tandem with an evaporator that includes wicking posts, which would be in contact with end-wells 120a such that the wicking posts absorb condensate accumulated in the end-wells and transport the condensate back to the evaporator wick. However, wettability pattern 118a could also function with an evaporator that does not include wicking posts. Diagram 122 shows operation of wettability pattern 118a with an evaporator that does not include wicking posts. Condensate accumulates to form bulges at end-wells 120a. These bulges grow larger and come in contact with the opposing evaporator wick, thus transporting the condensate back to the evaporator wick, and initiating another cycle.

Wettability pattern 118b is designed to work with an evaporator that does not include any wicking posts. Unlike wettability pattern 118a, wettability pattern 118b includes two extra vertical stems at its two edges. The extra stems with their additional end-wells increase the ratio of wettable domains to non-wettable domains.

Wettability patterns, such as the wettability patterns shown in FIG. 3, can be created using a variety of techniques. One example technique includes coating a surface of a plate with a low-surface energy material, etching a pattern on the coated surface (e.g., using a laser), and treating etched regions of the coated surface so as to create a dual-wettability (biphilic) surface. Further details regarding this technique are provided below.

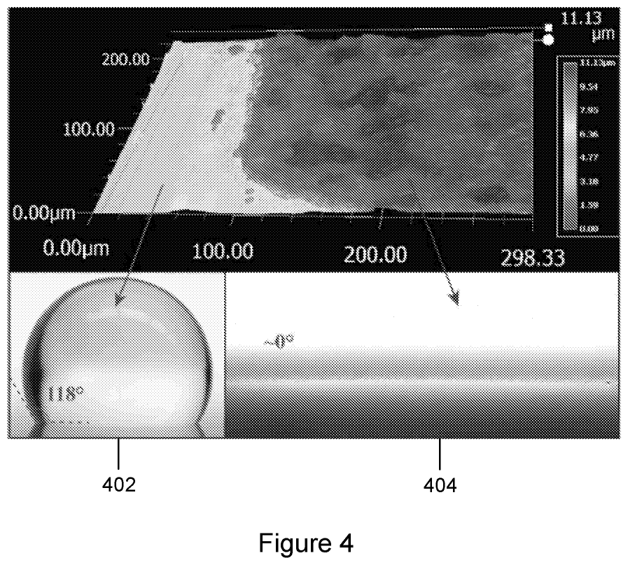

FIG. 4 shows the surface profile (top) of an example wettability-patterned condenser. The image in FIG. 4 was taken using an optical microscope. The maximum feature height difference was approximately 11 μm, as caused by a laser-etching process at the boundaries of the etched area. Most of the surface area, including etched and mirror-finish domains, spanned across the 0 μm to 4 μm height range, suggesting that the laser-patterning procedure did not add major features such as grooves or pillars on the substrate.

A first inset 402, on the bottom left of FIG. 4, shows the equilibrium condition for a 4.7 μL water droplet placed on a hydrophobic area of the surface: a contact angle of 118 degrees. A second inset 404, on the bottom right of FIG. 4, shows the equilibrium condition for a 4.7 μL water droplet placed on a superhydrophilic area of the surface: a contact angle of approximately 0 degrees.

In some examples, evaporator 104 of vapor chamber 100 is operably connected to a heat source of a system. For instance, the heat source can include an electronic device, such as a battery charger or a graphics processing unit. With this arrangement, vapor chamber 100 is configured to transfer heat from the heat source to wettability-patterned condenser 102 of vapor chamber 100. At the same time, vapor chamber 100 can block undesirable heat backflow while working as a thermal diode. For instance, vapor chamber 100 can hinder heat transfer from wettability-patterned condenser 102 to the heat source.

In other examples, the orientation of vapor chamber 100 with respect to the heat source can be reversed. As an example, wettability-patterned condenser 102 of vapor chamber 100 can be operably connected to a heat source of a system. For instance, the heat source can include the sun or a surface that is heated by the sun or a fire, and vapor chamber 100 can be an integrated component of a construction building material. With this arrangement, vapor chamber 100 is configured to hinder heat transfer (acting as a thermal diode) from the heat source to evaporator 104 of vapor chamber 100.

As such, vapor chamber 100 is usable in a variety of thermal management systems, such as a thermal management system of a device or system in aerospace, spacecraft, construction building materials, electronics protection, electronics packaging, refrigeration, thermal control during energy harvesting, thermal isolation, solar devices, electronic vehicles, electric aircraft, and optoelectronics. The heat output by the heat source can range from a fraction of 1 W/cm² to hundreds of W/cm².

Although vapor chamber 100 is shown as having a rectangular shape, the example is not meant to be limiting. In some instances, the heat source with which vapor chamber 100 is desired to operate may include a curved surface. Accordingly, wettability-patterned condenser 102 and evaporator 104 may be curved such that vapor chamber 100 conforms to the curved surface of the heat source (not shown). Further, vapor chamber 100 is operable in normal gravity environments, reduced gravity environments, and gravity-free environments.

### B. Hybrid Vapor Chamber Without Wicking Posts

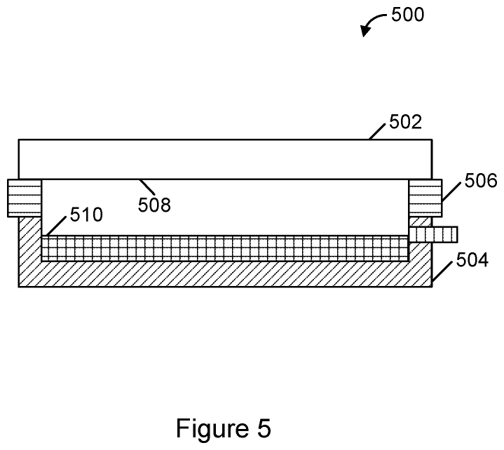

FIG. 5 illustrates a cross-sectional side view of an example vapor chamber 500. Like vapor chamber 100 of FIGS. 1 and 2, vapor chamber 500 includes a wettability-patterned condenser 502, an evaporator 504, and a spacer 506. Use of spacer 506 facilitates rapid replacement of evaporator 504 or wettability-patterned condenser 502. However, the presence of spacer 506 is not necessary. Rather than using spacer 506, wettability-patterned condenser 502 can be joined directly to evaporator 504.

A surface 508 of wettability-patterned condenser 502 includes a pattern of wettable domains that promote filmwise condensation and non-wettable domains that promote dropwise condensation. For instance, the pattern can include either of the wettability patterns shown in FIG. 3 or any of the patterns described herein. The pattern includes collection domains that accumulate condensate.

Like evaporator 104 of FIGS. 1 and 2, evaporator 504 includes an evaporator wick 510. However, unlike evaporator 104, evaporator 504 does not include any wicking posts that contact collection domains of wettability-patterned condenser 502. Instead, wettability-patterned condenser 502 and evaporator 504 are offset by a distance that is selected such that, as condensate bulges accumulate at the collection domains of wettability-patterned condenser 502, the condensate bulges contact evaporator wick 510 on evaporator 504.

### C. Example Fabrication Techniques and Device Characteristics

Hybrid vapor chambers, with and without wicking posts, have multiple different features. Experiments were performed to test the properties of hybrid vapor chambers. The following experimental vapor chambers and experimental results are provided as non-limiting examples of designs and features of hybrid vapor chambers.

### a. Fabrication Techniques

A vapor chamber was comprised of two distinct copper parts: the wick-lined evaporator and the wettability-patterned condenser. The 63.5 mm×63.5 mm×3.2 mm copper plate (110 mirror-finish copper, McMaster-Carr) of the evaporator side had a 50.8 mm×50.8 mm×2 mm pocket milled on its mirror-finish side to provide the foundation for the in-house fabricated copper wick. The surrounding mirror-finish area was a square frame (width=6.3 mm) occupied by the gasket (EPDM rubber, McMaster-Carr). Thus, the effective surface area of the vapor chamber was 50.8 mm×50.8 mm. Three equidistant thermocouple grooves 15.9 mm apart, extending to the middle of the plate were machined on the other side of the evaporator with the middle one reaching the center of the square plate, which coincided with the center of the heater. On one side of the evaporator, perpendicular to the grooves, a 1.6 mm diameter through-hole was drilled and a 25.4 mm long copper tube (122 copper tube, 0.4 mm wall thickness, 1.6 mm OD, McMaster-Carr) was press-fitted and later used to evacuate the vapor chamber before startup. After the evaporator casing was completed, it was thoroughly cleaned to remove excess machining oils and other contaminants by subsequently rinsing with soap water, DI water, ethanol, acetone, ethanol, DI water and finally drying in a pressurized stream of nitrogen gas.

Two versions of the wick-lined evaporator were fabricated: one containing wicking posts and the other one without wicking posts. A 0.7 mm-thick layer of copper powder (spheroidal, 10-25 μm, Sigma-Aldrich) was laid in the 50.8 mm×50.8 mm evaporator plate pocket and a 50.8 mm×50.8 mm×2 mm graphite frame with 16 evenly distributed, 3.2 mm diameter holes was placed on top of the powder layer. To fabricate the wicking posts, the graphite-frame holes were filled with the same copper powder, making the posts part of the evaporator wick, otherwise they were left empty. The sample, filled with copper powder, was then sintered at 900° C. for 10 min in a single-zone tube furnace (MTI corp., OTF-1200X-80-F3LV-PTFE) in reducing atmosphere (90% Argon, 10% Hydrogen), with a ramp rate of 20° C./min. The graphite frame was used regardless of whether wicking posts were being fabricated or not, to ensure same sintering conditions that resulted in identical final base-wick porosity of ε=0.67. The final porosity of the wick was calculated based on its dimensions after sintering and the weight of the copper powder used. An approximate permeability

K=dₚ²ε³/150(1−ε)²

and pore radius r=rₚ=0.21 dₚ were calculated from packed sintered sphere approximations, where dₚ is the copper powder particle diameter, here 17 μm. The thickness of the wick after the sintering procedure was 0.5 mm. The permeability and pore radius were found to be 5.32×10⁻¹² m² and 3.57 μm, respectively. The post height was carefully selected along with the thickness of the gasket so that when the device was sealed, the posts barely touched the condenser, allowing for proper contact and condensate recirculation while preventing post distortion due to mechanical compression. After the sintering process, the graphite frame was removed and the connection between the copper tube and the evaporator plate was sealed with epoxy (Gorilla, two-part epoxy) to prevent leaking.

The condenser side of the vapor chamber was fabricated from 63.5 mm×63.5 mm×1 mm copper plate (110 mirror-finish copper, McMaster-Carr) with three identical—in terms of dimensions and position on the evaporator—thermocouple grooves milled on the non-mirror-finish side. The samples were first cleaned with the same process followed to clean the evaporator plates. The mirror-finish surface was functionalized by spin-coating Teflon AF (Chemours AF 2400, 1% solution) at 2000 rpm for 20 s. The sample was then cured in the same furnace where sintering of the evaporator was performed under reducing atmosphere to prevent oxidation, which would have decreased copper thermal conductivity, and to increase the adhesion and conformity of the coating on the surface of the substrate.

The curing process was specific to the Teflon solution used and included heating up the coated substrate in a stepwise fashion (20° C./min ramp rate) to reach the boiling point of the solvent (160° C. for 10 min), then the glass transition temperature of the polymer (240° C. for 5 min) and the final adhesion-promoting temperature (330° C. for 15 min) suggested by the manufacturer. At this point of the process, the mirror-finish surface of the sample was hydrophobic. The sessile contact angle of this surface for a 4.7 μL water droplet was 118.0°±1.0° with 16.3°±1.5° contact angle hysteresis.

Next, a YB fiber laser (Tykma Electrox, 20 W) operated at 60% power, 10 kHz pulse frequency, 200 mm/s rastering speed with 0.02 mm spacing between rastering lines, was used to pattern the surface by selectively etching away part of the coating and lightly texturing the underlying metal surface. The laser-processed sample was then immersed in an aqueous solution containing 2.5 mol/L sodium hydroxide (Sigma-Aldrich, 50% in H₂O) and 0.1 mol/L ammonium persulfate (Sigma-Aldrich, ACS reagent, ≥98.0%) at room temperature for 5 min. In this immersion process, only the laser-treated domains were nanostructured via copper hydroxide formation, while the Teflon-coated mirror-finish areas remained unaltered. The nanotextured areas were superhydrophilic with a contact angle of ˜0° and passivated as required for the current experiment, remaining superhydrophilic throughout the tests. The maximum feature height difference at the edge of a patterned track was ˜11 μm, as caused by the laser-etching process at the boundaries of the etched area. Most of the surface area, including etched and mirror-finish domains, spanned across the 0 μm to 4 μm height range, suggesting that the laser-patterning procedure did not add major features such as grooves or pillars on the substrate.

The exemplary vapor chamber was placed on a 76.2 mm×76.2 mm×40 mm Teflon block with a 1 mm deep 63.5 mm×63.5 mm pocket milled on it to ensure proper positioning of the device relative to the heater. The 9.525 mm×9.525 mm×1 mm resistive heater (Component General, CPR-375-1, chip surface mount resistor, 350W) was embedded at the center of the Teflon block and its center was aligned with the end of the middle thermocouple groove on the evaporator, so that the heating element temperature could be accurately measured. A thin layer of thermally conductive paste (Omegatherm 201, Omega) was laid on the exposed side of the heater to minimize contact resistance with the vapor chamber. The heater output was controlled by regulating the voltage through a DC power supply (Volteq HY10010EX), and an ammeter (Adafruit Industries LLC, Ammeter 0-9.99A) was connected to the circuit to obtain an accurate reading of the current through the heater. On the other side of the vapor chamber, where another thin layer of thermally conductive paste was laid, a liquid cold plate was placed (TETechnology, LC-SSX1) to take away heat and allow for condensation to happen on the condenser plate inside the vapor chamber. The liquid cold plate was connected to a chiller (Neslab RTE-110) set at 21° C. in order to simulate ambient-temperature, active cooling conditions. Thermocouples (Omega, K-type, bead diameter 0.13 mm) were positioned at the inlet and outlet of the cold plate to monitor the cooling liquid temperature. In addition, six more thermocouples were secured in the thermocouple grooves on the outside of the vapor chamber with the aid of thermally conductive paste. Temperature data were recorded using a data acquisition system (Omega DAQ, USB 2400 series) at a sampling frequency of 1 Hz. An additional 127 mm×76.2 mm×19 mm block of Teflon was added on top of the liquid cold plate to minimize losses to the surrounding environment.

All components described above were clamped together between two metal plates, tightened by four screws, and fastening nuts in order to provide adequate sealing of the vapor chamber and proper thermal contact between the layered components. In addition, the whole setup was positioned on a stage that could rotate from 0° (horizontal) to 90° (vertical) so that the device could be tested at different orientations with respect to gravity. Finally, the vacuum pump (Alcatel Annecy 2008A) used to evacuate the chamber and degas the charging liquid, was connected to the vapor chamber via the copper tube on the evaporator side through leak-proof tubing, one shut-off valve and a needle valve in series. The shut-off valve was closest to the vapor chamber and a vacuum gauge was also mounted in between the two valves to monitor the pressure during the evacuation process.

### b. Thermal Resistance

The performance of the assembled exemplary device was evaluated using the thermocouples strategically placed around the copper shell. The recorded temperatures were used to calculate the total device thermal resistance Rₜₒₜ[K/W] as

$${R}_{t o t} = \frac{{T}_{h} - {T}_{c}^{a v g}}{{Q}_{i n}}$$

where Tₕ is the highest temperature on the device measured by a thermocouple sandwiched between the device and the heating source, T_{c}^{avg} is the average temperature of the condenser side of the device, and Qᵢₙ is the heat input, as determined from the applied heater voltage and current. The thermal resistance of the entire vapor chamber is comprised of several constituent thermal resistances within the device.

The amount of water encased in the device constitutes a parameter that affects its performance at different heat loads, and can be quantified by the charging ratio η defined as

$$η = \frac{Water Volume}{Vapor Chamber Empty Space} = \frac{{m}_{w} / {ρ}_{w}}{{V}_{VC}}$$

where m_{w} is the water mass inside the device during operation, σ_{w} the density of water, and V_{VC} the volume of the empty space inside the vapor chamber, which did not include the porosity of the wick or wicking posts, when present. The optimum charging ratio occurs when the device thermal resistance has been minimized. This ratio depends on the outer dimensions of the chamber, the wick thickness and porosity, and the condenser wettability pattern. All these parameters were investigated experimentally.

Another parameter is defined to specify each wettability pattern on the condenser plate. This parameter Φ, is defined as the ratio of the superhydrophilic condenser area (laser etched and chemically processed), divided by the total condenser area. Thus,

$$Φ = \frac{Superhydrophilic condenser area}{Total condenser area}$$

Superhydrophilic areas promote condensate nucleation and result in FWC, while hydrophobic areas promote DWC, thus delaying or completely preventing transition to FWC. Φ is essentially a measure of the FWC area in comparison to the DWC area of the condenser.

After the vapor chamber setup is assembled, the device is allowed to reach thermal equilibrium with the cold plate (˜21° C.) before the heater is turned on. As mentioned earlier, the resistive heater power output is controlled through the input voltage, which is increased in a stepwise fashion in 5 V increments starting at 10 V. Every time the voltage is increased to a certain level, the exemplary system is allowed to reach steady state before the next step up. It was found throughout the experiments that 4 min were enough for the exemplary vapor chamber to achieve steady state, in addition to allowing a full minute of steady-state data to calculate the device performance. Each experiment was repeated 3-5 times for each charged device to ensure repeatability. The maximum heat input imposed during the experiments was dictated by the device reaching thermal runaway or, more frequently, the heater approaching its temperature safety limit, both limits which could vary based on the characteristics of a particular system or device, in accordance with the principles herein.

Wettability pattern 118a and wettability pattern 118b of FIG. 3 were used in the experiments. The ratio Φ for wettability pattern 118a was 0.40, meaning that 40% of the total condenser area was superhydrophilic. The ratio Φ for wettability pattern 118b was 0.65.

To establish a control case for the wettability-patterning approach, a plain mirror-finish copper plate was first used on the condenser side of the vapor chamber. A wick-lined evaporator with a 0.5 mm-thick wick and no wicking posts was used on the evaporator side of the control device.

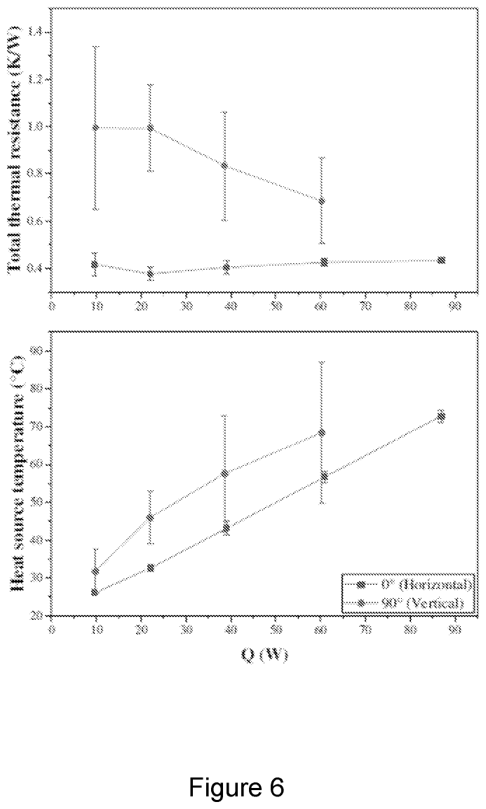

FIG. 6 shows the results of the experimental runs for the control device. The mirror-finish copper static contact angle was 79.3°±1.5°, with a contact angle hysteresis of 68°±7.9°. The total device thermal resistance with respect to the heat load applied is shown in the top panel, and for two different orientations with respect to gravity: horizontal placement at 0° (square line markers) and vertical placement at 90° (circle line markers).

Heat source temperature versus heat load is presented at the bottom panel of FIG. 6. The optimum charging ratio was found to be ˜14%. This translated to a 0.38 K/W lowest total thermal resistance at 22 W heat load when the chamber operated horizontally. The device thermal resistance starts at 0.42 K/W at 9.7 W and slightly rises at higher heat loads, after the minimum, reaching 0.43 K/W at 86.9 W. At this power, the experiment was stopped in order to avoid damaging the heater, as further increasing the heat load resulted in high fluctuations of the heat source temperature and increased absolute values.

By examining the vertical case, an entirely different performance is showcased, one that is significantly worse than before, with the device total thermal resistance being at least 60% higher at all heat loads and with high variance. This is attributed to the fact that gravity is affecting the performance of this control device, due to the lack of any proper condensate handling mechanism on the condenser, such as a wick or wettability patterns. This way, water condensate moves erratically due to uncontrolled coalescence phenomena and gravity effects, until droplets become large enough to touch the evaporator wick and get transported to that side of the device. The vertical device was unable to function past 60 W due to thermal runaway, presumably caused by the erratic nature of solid, water and gravity interactions inside the device.

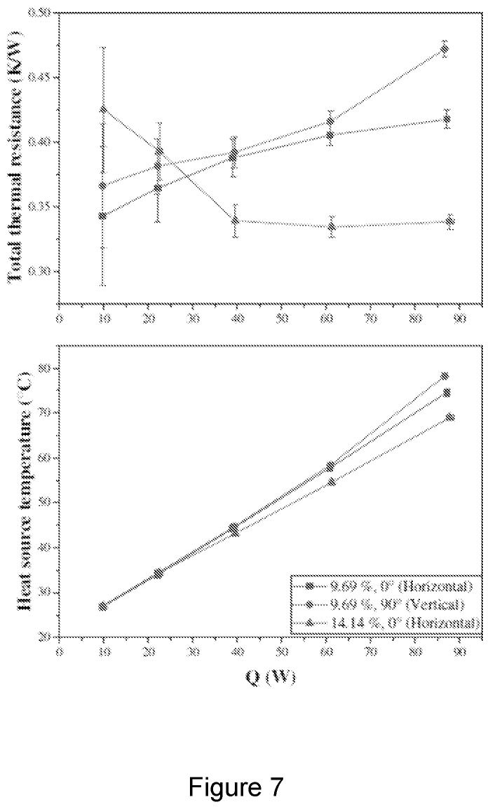

Following the control experiment, an exemplary device without posts but with a wettability pattern was tested next. The pattern used in this case was wettability pattern 118a of FIG. 3. Three different cases are shown in FIG. 7, for two different charging ratios and two different orientations for one of the ratios. The results shown for higher charging ratio represent the best-performing conditions for this exemplary device at a horizontal orientation (triangle line markers). The vertical orientation is not shown here for this specific charging ratio, as these experiments were performed before the rotational ability was added to the experimental setup. For this reason, the experiments were repeated after the setup was upgraded, in order to test the gravity-dependent performance of the device. However, the exact same charging ratio could not be attained due to difficulties in estimating the exact amount of charging liquid lost during the complex assembly and evacuation procedures.

The different charging ratio achieved in these follow-up experiments, is presented here not only to showcase the behavior of a vertically-positioned vapor chamber, but also to show the effect of a lower-than-optimum charging ratio on the thermal resistance curve trend. By examining the total thermal resistance curve for 14.14% in FIG. 7 (top panel), the slope is negative from 10 W to 40 W, starting from 0.43 K/W and reaching 0.33 K/W, thereafter, remaining flat up to ˜90 W. At this point, the device had still not reached thermal runaway; nonetheless, the heat load was not increased further in order to protect the heating element. This represents a significantly better device operation than the control case with a lower charging ratio, which means an overall lighter device (crucial for applications where weight matters, e.g. consumer electronics).

Shifting attention to the curves for 9.69% charging ratio, it is evident that this is an undercharged device, operating with almost half the ideal charge. The total thermal resistance curve for the horizontally positioned device (square line markers) starts lower than the 14.14% one, at 0.34 K/W for a 10 W heat load, but the slope is positive, this time showing a continuously increasing thermal resistance up to 0.42 K/W at ˜90 W. By comparing the two charging ratios at the horizontal orientation, it is important to notice that the thermal-resistance error bars are large at low heat loads, although the mean values of one curve are not within range of the standard deviation of the other curve, thus making the differences statistically significant, albeit close.

It is interesting that the thermal resistance of a device that is undercharged is lower than with the optimum charging ratio at low input powers. This result can be explained by the fact that at low charging ratios the evaporator wick is not fully saturated, meaning that there is a smaller distance between the heated bottom of the device and the free surface of the liquid. So for these lower heat loads where the evaporator temperature is also lower, a higher superheat, which is defined as the temperature difference between water free-surface and saturated vapor, can be achieved in comparison to a fully-saturated wick, where the distance between the heated bottom and the water free surface is larger, thus posing a higher thermal resistance. However, this behavior cannot sustain high heat fluxes due to the increased need for more charging liquid to maintain phase-changing medium circulation, as more vapor is being generated, which leads to partial dry-outs in the evaporator wick, thus increasing thermal resistance and eventually leading to thermal runaway. Separately, the curves corresponding to the horizontal and vertical orientations (circle line makers) for the 9.69% device, the results overlap from 10 W to ˜60 W, showcasing the gravity-independent operation of the specific wettability pattern for this range of heat loads. The thermal-resistance curves only begin to diverge beyond this power, with the vertically-orientated device showing an increase in total thermal resistance at 0.47 K/W for ˜90 W applied heat load, the end of the current experiment, since the heater temperature rose to unsafe, for the heat source, levels.

The heat source temperature with respect to heat load graph at the bottom of FIG. 7 shows all three devices starting at the same level (˜27° C.), with the 14.14% curve having the smallest slope and diverging first at ˜40 W. The curves corresponding to the 9.69% charging ratio for the two orientations follow closely up to ˜60 W, where the vertically-oriented device diverges slightly, similarly to the thermal resistance trend. The highest temperature differences observed at 90 W are 6° C. between the two charging ratios at the horizontal orientation, and an extra 4° C. for the vertically-positioned 9.69% charged device.

The same wettability pattern was then applied to a device with wicking posts. This pattern was specifically designed to work in tandem with wicking posts. The current experiments were performed before the setup included the ability to turn vapor chambers in the vertical orientation, so only curves for the horizontal orientation are shown here.

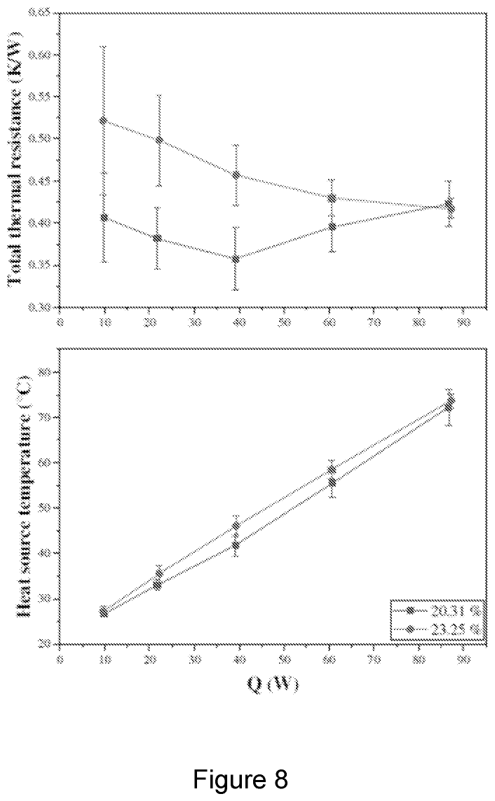

The results from the best performing device are shown in FIG. 8, along with the results from a slightly overcharged device, in order to highlight the differences of this second charging ratio scenario. A charging ratio of 20.31% (square line markers) was found to generate the best results, i.e. lowest total thermal resistance, 0.36 K/W at ˜40 W. The curve slope was negative at low heat loads as expected, with the thermal resistance rising slightly after 40 W until it reached 0.42 K/W at ˜90 W. Once again, the experiment was terminated at this specific heat load due to the heater temperature reaching ˜100° C. at further increased powers. A slightly overcharged device at 23.25% is also presented in FIG. 8 (circle line markers), having a negative slope (thermal-resistance curve) throughout the entire power range. The device shows a 27% higher thermal resistance at the starting heat load of ˜10 W and decreases until 90 W where it matches the thermal resistance of the device charged with the 20.31% ratio. At this heat load, both devices have the same effect on the heat source temperature; the experiment was terminated at this power to protect the heating element.

Overall, the device charged at 20.31% is performing better for the whole range of heat loads examined, therefore it is designated as the optimally-charged device. In the case of an overcharged device, thermal resistance is higher at low heat loads since the evaporator wick is oversaturated, thus affecting thin-film evaporation, which reduces the evaporation rate, thus increasing the overall thermal resistance. However, as the temperature rises and more vapor is generated inside the device, the ratio of liquid to vapor changes, and more regions of the evaporator wick begin operating more efficiently, entering the thin-film evaporation regime, decreasing the device thermal resistance and approaching optimum conditions.

It was evident that a device had been oversaturated when, after the conclusion of the tests, the device was disassembled and water was observed pooling on top of the evaporator wick either covering part of its surface area or all of it, depending on the amount of oversaturation. For an application with a range of heat loads and temperatures that surpasses that of the current experiment, the 23.25% ratio could potentially outperform the 20.31% since the thermal resistance with heat load appears to be monotonic and the current range of experiments did not show signs of thermal runaway up to 90 W. Thus, a different heating source that allows for higher temperatures to be reached, could reveal a different behavior of the overcharged device, in accordance with the principles herein.

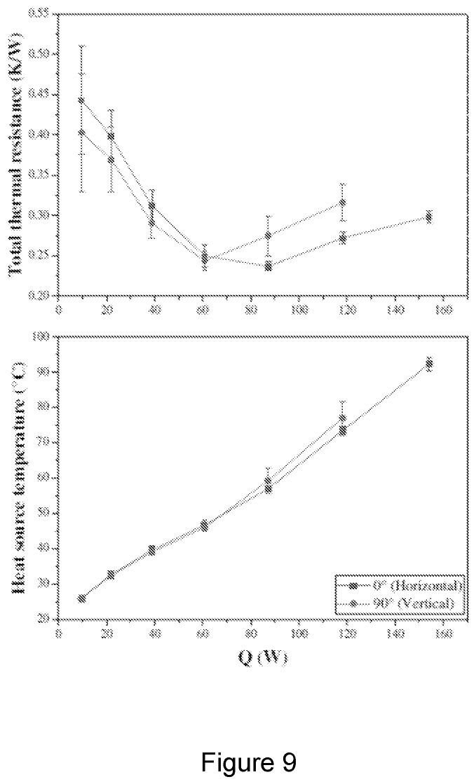

A vapor chamber with wettability pattern 118b of FIG. 3 was tested next with a 0.5 mm-thick evaporator wick, but in the absence of wicking posts. Wettability pattern 118b features two extra rows of drainage stems at the edges of the condenser plate, each including four extra end-wells. Only results from the optimum charging ratio (21.89%) are presented in FIG. 9 for both extremes of device orientation (0° (square line markers), 90° (circle line markers)).

It is evident that the device performs in an identical way at both orientations and power inputs from 10 W to 60 W. At that power, the thermal resistance of the device placed horizontally continues dropping with rising power until it reaches 0.24 K/W at 87 W heat load, which is the lowest resistance achieved up to this point. On the other hand, when the device is vertically oriented, thermal resistance reaches its lowest value (0.25 K/W) at 60 W and begins ascending again with rising input power. The experiment was terminated for the vertical placement at 120 W and resistance 0.32 K/W, 20% higher than the resistance for the same heat load at the horizontal orientation. After this point, the device went to thermal runaway when vertically-oriented. This result shows that the current wettability pattern is gravity-independent at heating powers up to 60 W, and it can still operate with higher efficiency than other devices at any orientation up to 120 W. The same device positioned horizontally can handle 154 W heat load without approaching thermal runaway. Note that higher powers were not applied for the sole purpose of protecting the heater.

It is important to note here that a significantly wider heat load range was examined in this case (10 W-154 W) in comparison to all previous cases (10 W-90 W). The present device showed a significantly lower thermal resistance, which allowed for better heat dissipation as intended with vapor chambers, that kept the heat source temperature lower throughout the course of the experiment, and in turn, allowing for higher heat loads to be accommodated. Namely, the heat source temperature at 154 W was stable at ˜91° C. showing no sign of thermal runaway, and lower than 80° C. for both orientations at 120 W, when all devices tested before operated at 70° C. −80° C. under a lower (90 W) heat load.

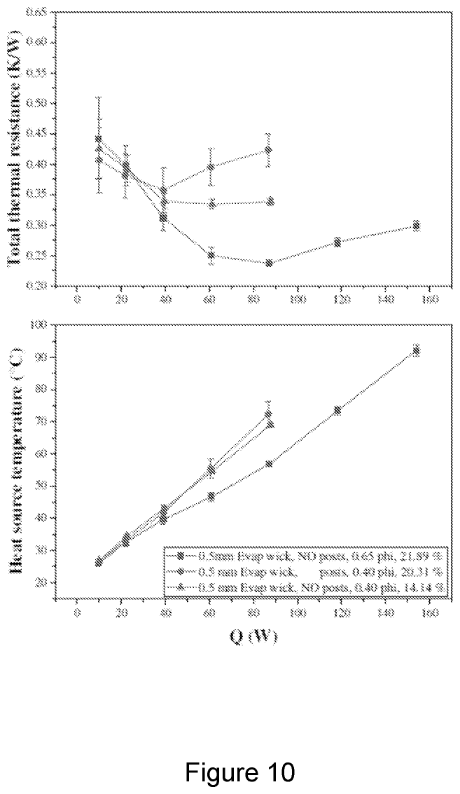

FIG. 10 shows results for the best-performing exemplary devices operating at their optimum charging ratio and horizontal orientation. The total thermal resistance (top) and the heat source temperatures (bottom) are plotted against the applied heat load. It is evident that the device without wicking posts and a wettability pattern with Φ=0.65 (square line markers) outperforms the other devices not only by its 37% lower total thermal resistance compared to the second best-performing device (triangle line markers), but also by being able to operate at a wider range of heat loads. The heat source temperature graph clearly shows how the Φ=0.65 design provides better thermal management of the heating element, by maintaining its temperature at the lower level within the range of heat loads explored here. Specifically, at 90 W where the rest of the devices reached their limits, the temperature of the heat source of the device with Φ=0.65 was 20% lower than the second best-performing device. This makes the former device a better option as an all-around heat spreader for a cooling application under this heat load range. In addition, this device appears to be significantly more stable than other devices even under vertical orientation, only being limited to work up to 120 W, vs. 90 W of the second best-performing device.

### c. Thermal Diodicity

The characterization “thermal diode” has been used to portray systems that spread heat very efficiently in a specific direction but obstruct it from flowing in the opposite direction. The diodicity or thermal rectification of a thermal directional system is defined as

$$γ = \frac{{k}_{F W D} - {k}_{R V S}}{{k}_{R V S}}$$

where k denotes the effective thermal conductivity along x and across an area A, and is given by

$$k = \frac{Q d x}{A Δ T}$$

where dx is the total thickness of the system (hot to cold side), and ΔT the difference between the average temperatures of the hot and cold sides.

The hybrid vapor chambers disclosed herein are also capable of functioning as thermal diodes. To demonstrate this feature, a hybrid vapor chamber was tested as a thermal diode. The assembly components for the hybrid vapor chamber were: a wick-lined evaporator, a wickless condenser, and a gasket.

The wick-lined evaporator was fabricated from a mirror-finish copper plate with dimensions 63.5 mm×63.5 mm×3.175 mm. On this plate, a pocket was milled with dimensions 50.8 mm×50.8 mm×2 mm. The remaining surrounding mirror-finish area was meant to provide the seat for a sealing gasket. On one side of the evaporator, a 1.6 mm diameter hole was drilled, and a 25.4 mm long copper tube was press-fitted inside this hole. This pipe was later used to evacuate the VC before startup. The copper tube was sealed on the evaporator plate with epoxy to prevent leaking. A 0.7 mm-thick copper wick was laid in the milled pocket. To achieve that, the sample was filled with copper powder and sintered at 950° C. for 15 min in a single-zone tube furnace (Lindberg, Blue-M-HTF55322c) using a heating ramp rate of 20° C./min, inside a reducing atmosphere consisted by 90% Ar and 10% H₂.

Two wickless condensers equipped with wettability patterns were fabricated. One of the condensers was equipped with wettability pattern 118a of FIG. 3, and the other condenser was equipped with wettability pattern 118b of FIG. 3. These parts were produced from a mirror-finish copper plate with dimensions 63.5 mm×63.5×1 mm. For each condenser, the surface was functionalized by spin-coating Teflon AF (AF 2400, Amorphous Fluoroplastics Solution, Chemours Co.). The sample was then cured in the same furnace in three stages, namely 80, 180 and 260° C. Next, a laser marking system (EMS400, TYKMA Electrox®, 80% power, 10 kHz intensity, 200 mm/s traverse speed) was used to etch the desired pattern. The laser selectively ablated the Teflon coating from the coper plate, rendering the treated domains superhydrophilic.

The process continued by immersing the plate sample in an aqueous solution of 2.5 mol/L sodium hydroxide (Sigma-Aldrich, 415413-500ML) and 0.1 mol/L ammonium persulfate (Sigma-Aldrich, ≥98%, MKCF3704) at room temperature for 5 minutes. The goal of this step was to cover the laser-etched regions with copper hydroxide nanoneedles (for added texture), while at the same time, keeping the Teflon-coated mirror-finish regions hydrophobic. The final product was a wick-free copper plate with a superhydrophilic pattern laid in hydrophobic surroundings.

The gasket was designed to disassemble and reassemble the system in a resource-efficient step that enables repeated testing. This gasket allowed the chamber to remain sealed for the entire period of each experimental run, while also allowing easy disassembly at the end of each run.

For the sealing mechanism, two metal plates secured by four parallel cylindrical posts were used to provide the appropriate sealing and effective contact between the experimental components.

For thermal insulation, three distinct insulators were used. A Teflon block (8735K67 McMaster-Carr) with dimensions 73.2 mm×73.2 mm×12.7 mm covered the upper part of the cold plate. A second Teflon block (8735K67 McMaster-Carr, PTFE) with dimensions 76.2 mm×76.2 mm×25.4 mm insulated the lower part of the heater. Around the outer sides of the lower Teflon block, a 25.4 mm thick Ceramic Fiber Insulation (B015GD0QCW—Amazon) block was placed. Consequently, the Teflon parts insulated the heater, the chamber, the copper block on top of the heater, and the cold plate from their surroundings, thus facilitating one-dimensional heat transfer.

For the heat-transfer assembly, on the upper side of the diode, a liquid-cooled plate was placed (TE Technology, LC-SSX1), functioning as heat sink removing heat from the system in a controlled manner. This plate was connected to a chiller (Neslab RTE-110) circulating pure ethylene glycol (Alfa Aesar, Ethylene Glycol 99%) and maintaining the cold plate temperature at 30° C. The vapor chamber was positioned underneath the cold plate, on top of a copper block surrounded by a Teflon rectangular frame. The copper block had a shallow (1 mm-deep) 63.5 mm×63.5 mm milled pocket to ensure proper seating of the diode inside the block (89275K35 McMaster-Carr Multipurpose 110 Copper Bar), which had dimensions 50.8 mm×50.8 mm×9.5 mm. This copper block was implanted in a Teflon frame (8735K67 McMaster-Carr Bar, PTFE) with dimensions 76.2 mm×76.2 mm×10.5 mm. A flexible heater (Omegalux, KH-303/10-P, 90W) with dimensions 76.2 mm×76.2 mm×0.254 mm was the heat source. The heater output was controlled by regulating the voltage through an AC power supply (Staco Energy Products Co, Type 3, 3PN1010).

The geometric centers of both blocks were aligned with the centers of the vapor chamber and the flexible heater. The objective of this placement was to enable heat flow to the vapor chamber in the most unidirectional way from the heater through the copper block to the wick-lined area of the chamber. The heat transfer up to this point relied on conduction. To minimize contact resistance, a thin layer of thermal conductive paste (Omegatherm 201, Omega) was spread over every interface through which heat flowed.

A vacuum pump (Alcatel Annecy 2008A) was utilized to rid the closed system of air and non-condensable gases. The pump was attached to the vapor chamber via the copper tube on the evaporator side through leak-proof tubing, an on/off valve, and a flow-regulating valve connected in series. The on/off valve was nearest to the vapor chamber and a vacuum gauge was attached in between the two valves to monitor the pressure during the evacuation procedure. Moreover, six thermocouples (TCs) were positioned in TC grooves on the outside of each copper plate. On the TC tip, conductive paste was placed to ensure accurate temperature reading and data collection. Temperature data was recorded using a data acquisition system (Omega DAQ, USB 2400 series) at a sampling frequency of 1 Hz. A voltage regulator (Staco Energy Products Co, Type 3, 3PN1010) was utilized to modulate the heat input provided to the chamber by adjusting the voltage.

In a forward (FWD) mode, the copper wick-lined component is on top of the copper block with three thermocouples (TC1, TC2, and TC3) attached in between. Originally, the wick is filled with the desired water quantity. The gasket is positioned on top of the flange around the wick of the evaporator. Thermocouples TC4, TC5, and TC6 are placed between the wickless condenser and the cold plate heat sink. After the chamber was sealed, the first pump down procedure evacuated the chamber.

The initialization procedure was continued by heating up (from room temperature to 40° C.) the system for 30 minutes, followed by a second degassing stage until the system's internal pressure reached approximately 4 kPa. Subsequently, the system was left to equilibrate down to 30° C. and the initialization procedure ended. Three experimental runs were completed under the same conditions to produce error estimates. Each experimental run for the FWD mode lasted 7 minutes, while each reverse (RVS) mode run lasted 10 minutes, with both time frames found adequate to reach steady state. The data from the last 100 seconds of each run were used for the analysis. When an experimental run ended, the system was left to equilibrate again at 30° C., and the next cycle started. TC1, TC2 and TC3 recorded temperatures between the copper block and the evaporator, while TC4, TC5 and TC6 provided the temperatures between the condenser and the cold plate. Those temperatures were used to monitor the lateral temperature uniformity on both sides of the chamber.

In the RVS mode, the same experimental procedure was followed, but with a change in the vapor chamber placement, namely, the system was upturned, with the wick-free plate brought to contact with the heated copper block, while the wick-lined part came in contact with the cold plate.

Throughout the evacuation procedure, a loss of vapor mass took place since the system was pre-charged with DI water. The weight of the chamber was determined shortly after the experiment was finished to determine the vapor loss. The chamber was disassembled and left open to dry for 8 hours on a weight scale. Following full dry out, the weight of the chamber parts was again measured. During each experiment, the weight difference before and after the dry-out process produced the weight of the working medium (DI water) within the chamber.

The heat passing through the system was determined by the following procedure. One-dimensional heat was generated by the flexible heater, assuming no heat losses to the environment. This assumption is justified by the small heater thickness (0.254 mm) and the insulation placed all around the heater area. An order of magnitude analysis supported this assumption.

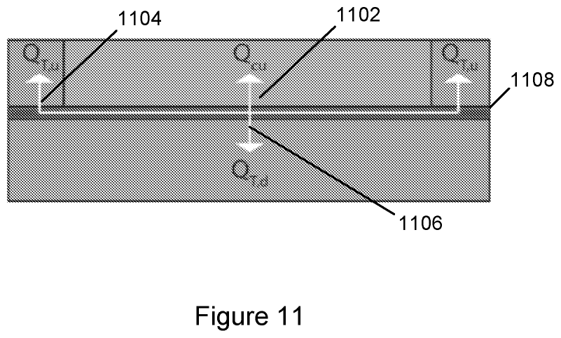

FIG. 11 shows pathways 1102, 1104, 1106 along which heat generated from a flexible thin heater 1108 can spread inside the experimental setup. Pathway 1102 shows spread through the copper block, Q_{cu}. Pathway 1104 shows spread through Teflon blocks on the sides of the copper block, Q_{T,u}. Pathway 1106 shows spread through the Teflon block under the heater, Q_{T,d}.

The spread through the copper block Q_{cu} prevails, as it occurs through the high-conductivity metal. The total heat produced by the heater (Qₜₒₜ) is distributed among the copper block (Q_{cu}), the Teflon blocks around the copper (Q_{T,u}), and the Teflon block under the heater (Q_{T,d}), i.e.

Qₜₒₜ=Q_{cu}+Q_{T,u}+Q_{T,d}

From Fourier's law, Q can be expressed as

$$Q = k A \frac{d T}{d x}$$

Combining these two equations, the total heat can be expressed as

$${Q}_{t o t} = {k}_{c u} {A}_{c u} \frac{d {T}_{c u}}{d {x}_{c u}} + {k}_{T} {A}_{T , u} \frac{d {T}_{T , u}}{d {x}_{T , u}} + {k}_{T} {A}_{T , d} \frac{d {T}_{T , d}}{d {x}_{T , d}}$$

with property values and parameter magnitudes as shown in the following table:

| | Parameter/property Values and Magnitudes | | | |
|---|---|---|---|---|
| Symbol | Description | Value | | Magnitude |
| K_{cu} | Conductivity of copper | 385 | W/mK | O(10²) |
| K_{T} | Conductivity of Teflon | 0.32 | W/mK | O(10⁻¹) |
| A_{cu} | Area of copper block | 0.0025 | m² | O(10⁻³) |
| A_{T, u} | Area of Teflon (top) | 0.0032 | m² | O(10⁻³) |
| A_{T, d} | Area of Teflon (bottom) | 0.0058 | m² | O(10⁻³) |
| dx_{cu} | Thickness of copper block | 0.00925 | m | O(10⁻³) |
| dx_{T, u} | Thickness of Teflon plate (top) | 0.01025 | m | O(10⁻²) |
| dx_{T, d} | Thickness of Teflon plate (bottom) | 0.0127 | m | O(10⁻²) |
| δT_{cu} | Lateral temperature difference, copper | 2° | C. | O(10⁰) |
| δT_{T, u} | Lateral temperature difference, Teflon (top) | 40° | C. | O(10¹) |
| δT_{T, d} | Lateral temperature difference, Teflon (bottom) | 20° | C. | O(10¹) |

Substituting values from this table into the previous equation, it was deduced that the most important term on the right-hand side of the equation is Q_{cu}, which is three orders of magnitude larger than all other terms of this equation. Thus, the following formula has been used for Qₜₒₜ

$${Q}_{t o t} \approx {Q}_{c u} = {k}_{c u} {A}_{c u} \frac{d {T}_{c u}}{d {x}_{c u}}$$

The lateral temperature variations on the copper block δT_{cu} were minimal and close to the instrument error (˜0.5° C.). To minimize error propagation, another formula was utilized to determine the heater power with greater accuracy

$$Q = \frac{{V}^{2}}{{R}_{h e a t}}$$

where Q is measured in Watts, V is the voltage applied to the heater measured in Volts, and Rₕₑₐₜ is the electrical heater's resistance measured in Ohms (resistive load).

Total thermal resistance of the system is another performance metric of the vapor chamber, calculated as follows

$${R}_{t o t} = \frac{Δ T}{Q}$$

where Q is the heat input and ΔT the difference between the average temperatures of the hot and the cold sides.

There is a significant difference in the performance of the system at the two modes of operation. During FWD mode, the heat input is successfully removed from the heater via phase-change heat transfer. Throughout the RVS mode of the heat flow no considerable latent heat transfer is expected. The diodicity of the system is presented at a standard and constant ΔT where disproportionate magnitudes of heat (Q) are allowed to pass through. This unequal heat transfer can be quantified by the rectification coefficient γ.

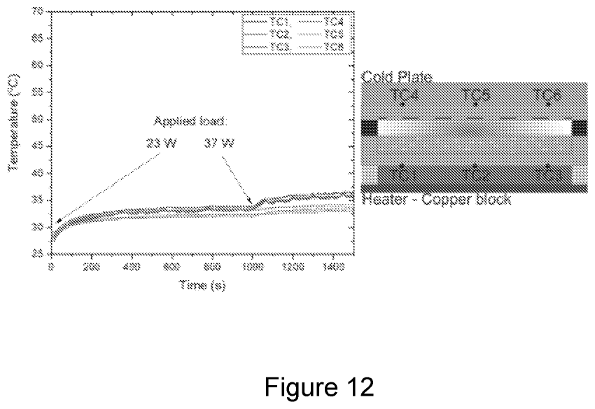

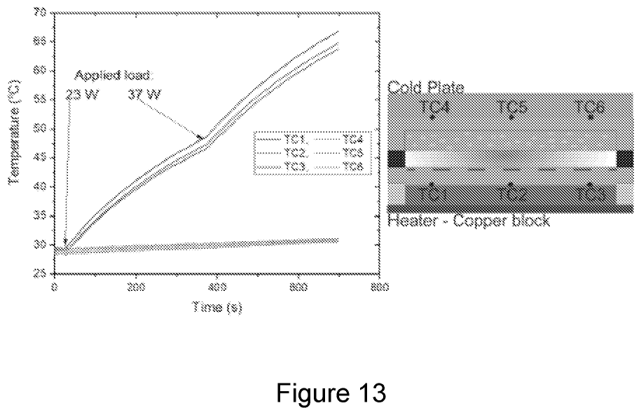

FIG. 12 shows data collected for a system with Φ=0.40, CR=21% operating in the FWD mode. FIG. 12 also shows (at right) the location of Thermocouples TC1-TC6 mentioned above. FIG. 13 shows data collected for the same system operating in the RVS mode. On the right side of FIGS. 12 and 13 are the two layouts of the vapor chamber orientation with respect to the heater, copper block and the cooling plate; the chamber is flipped by 180° in the RVS mode compared to the FWD mode. Two different heating loads were applied for each mode.

The two graphs emphasize how the same heat load affected performance when the apparatus operated in the two modes. For both cases, the system starts in thermal equilibrium at ˜29° C. In the FWD mode (FIG. 12), it is evident that the two applied heat loads create minor temperature differences between the evaporator and the condenser. More specifically, the 23 W heat load creates a ΔT=0.8±0.4° C., while the 37 W heat load creates a ΔT=2.2±0.4° C., where ΔT=Average (TC1,TC2,TC3)−Average (TC4,TC5, TC6). This happens because in the FWD mode the system works as a high-performance vapor chamber, in contrast to the RVS mode, where the system performs as a heat blocker.

In the RVS mode (FIG. 13), the two applied heat loads create major temperature differences between the evaporator and the condenser in a shorter time. Specifically, the 23 W heat load creates a ΔT=17.7±0.5° C., while the 37 W heat load creates a ΔT=34.1±0.8° C., eventually pushing the system to thermal runaway.

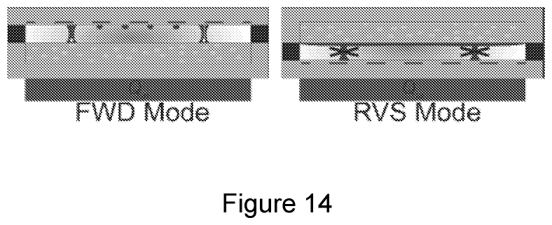

FIG. 14 illustrates the working principles of the diode in the forward mode and the reverse mode. The thermodynamic cycle of the present diode comprises of evaporation, condensation, and transport of condensate back to the evaporation (heated) point. The first two stages are governed by the temperature difference between the vapor core and the high and low temperature of each side respectively, while the fluid replenishment at the heated area is highly dependent on the physical design of the chamber. The distance between the two opposing plates (one acting as evaporator, the other as condenser), the amount of the sealed working fluid, the wick thickness, and the wettability pattern on the wickless plate are the main physical parameters affecting performance. In this study, only the fluid charging ratio and c were changed.

In the FWD mode (FIG. 14, left), the wick-lined evaporator intrinsically tends to hold the water evenly, while its higher temperature causes thin-film evaporation. When the water vapor reaches the wickless condenser on the opposite side, droplets start forming on the hydrophobic parts, while a film develops on the superhydrophilic parts. The droplets on the hydrophobic part grow until they contact the superhydrophilic areas or coalesce with each other first and then get transported to the main drainage vein through the wedge-shaped tracks. The circular reservoirs purposely designed along the superhydrophilic main tracks, due to their low curvature, form low Laplace pressure points, thus attracting the condensate being pumped through the tracks. As condensation progresses and more water is collected in the superhydrophilic domains, more water is transported to the low-pressure reservoir sites and bulges grow until they reach the wick on the opposing plate. At this moment, a capillary bridge forms between the condenser and the wick on the evaporator and water starts permeating through the wick until the capillary bridge becomes unstable and snaps due to water volume loss to the wick. Thus, a full cycle of evaporation and condensation is completed. The stability of this cycle is affected by the working fluid charging ratio, the number and size of low-pressure sites on the condenser and the heat flux forced through the system. These capillary bridges facilitate heat manipulation inside the vapor chamber since they determine the mass exchange between the hot and the cold sides of the chamber.

In the RVS mode (FIG. 14, right), the wickless plate acts as the evaporator. After evaporation, the water vapor condenses on the opposing wick, which is cooled in this case. The porous wick spreads the condensate laterally through capillary action. After the wick gets saturated with water, there is no direct mechanism to drive it back to the evaporator, since there is no physical connection between the opposing plates other than at their edges. The mass connection between the two plates in the FWD mode was made by the water bulges forming due to the wettability patterns. In the RVS mode, this cannot occur.

The distance from the patterned surface to the wick is 2.5 mm. Since the two working surfaces are close to one another and in the FWD mode the condensate accumulated in wells thus forming capillary bridges, the gravitational orientation does not play an important role for sustained operation. In the RVS mode, however, the gravitational orientation is more important, since the wick-lined condenser (top side), traps the condensate, which eventually drips down by gravity onto the wickless plate (bottom side) to complete the boiling-condensation cycle. This gravity-assisted operation of the RVS mode hinders the diodic performance of the system and was selected to quantify the system's diodicity as the worst-case scenario. In contrast, the best-case scenario to achieve even higher diodicity would be to place the cooling block at the bottom of the setup, underneath the wick-lined plate (operating as condenser) and the wickless plate (operating as evaporator) placed on top. This reverse placement would lead to sustained water accumulation at the bottom side of the system, where the gravity cannot assist the fluid to return to the evaporator (at top), thus blocking the condensate resupply mechanism, and in turn, causing even higher diodicity.

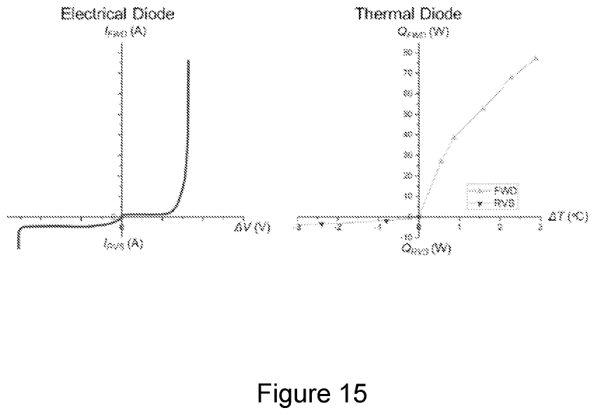

FIG. 15 illustrates diodic behavior of a hybrid vapor chamber. On the left-hand side of FIG. 15, a theoretical graph of an electric diode is presented. For this diode, the voltage differential is the x-axis and the electric current the y-axis. On the right-hand side of FIG. 15, the corresponding curve for the best-performing thermal diode of this study is presented. For both cases, the negative horizontal axis represents the reverse operation. In RVS operation, the electric diode does not allow the electric current to pass through. Similarly, in RVS operation of the present chamber, the heat transfer is mostly blocked.

The thermal analogue of the current is the heat, while the analogue of the voltage differential is the temperature difference between the evaporator and condenser plates. Among all cases studied herein, the greatest value of diodicity was γ=23.5±0.9. This case corresponded to an average effective thermal conductivity k_{FWD}=71.0±0.1 W/m−K in the FWD mode, and k_{RVS}=2.9±0.1 W/m−K in the RVS mode. These values were achieved with a wettability patterned plate having Φ=0.65 and a fluid charging ratio CR≈21%.

Thus, a vapor chamber that can act as a high-performance heat spreader in addition to acting as a directional thermal barrier. This system features a wickless wettability-patterned plate and an opposing wick-lined plate and is able to transport heat with a strong directional preference. The unique directional heat flow is ascribed to the core characteristics of the vapor chamber. The effective thermal conductivities for the forward mode and the reverse mode of operation were reported, and the diodicity was quantified and discussed. The working prototype was a thermal rectifier with high effective thermal conductivity in the forward mode. The low profile and light weight of the system are advantageous for scalability. The fabrication method is straightforward and scalable to larger dimensions, while the materials are durable and commonly used at industrial scale. The operating conditions of the present experiments emulated common microelectronics working temperatures. Thus, the present vapor chambers can be used for passive protection of sensitive electronics from reaching elevated temperatures and could be beneficial for a wide spectrum of other applications in thermal management, aerospace thermal systems, electronic packaging, or even exterior construction components in green buildings.

### III. Example Wick-Free Vapor Chambers

As noted above, the use of wettability patterning on a condenser of a vapor chamber can lower the device total thermal resistance of a vapor chamber. In order to completely reap the advantages of wettability patterning in heat transfer applications, the use of wettability patterning can be extended to the evaporator of vapor chamber. By way of example, the evaporator wick of a hybrid vapor chamber can be replaced with a wickless surface, consequently creating a wick-free vapor chamber.

In accordance with the principles herein, systems and devices can be achieved where fluids can be transported pumplessly on open planar surfaces, while the combination of different patterns can enhance the condensation heat transfer. Advantages that wick-free vapor chambers provide include the reduction of the total thermal resistance, the minimization of the dimensions of the vapor chamber, and the ability to laterally spread heat while being free of metal wicks or wicking structures. Moreover, creating a wick-free vapor chamber is easier and more cost-effective than sintering wicks.

As used herein, a vapor chamber having a wettability-patterned condenser and a wettability-patterned evaporator is referred to as a wick-free vapor chamber.

### A. Illustrations, Patterns, and Working Principles

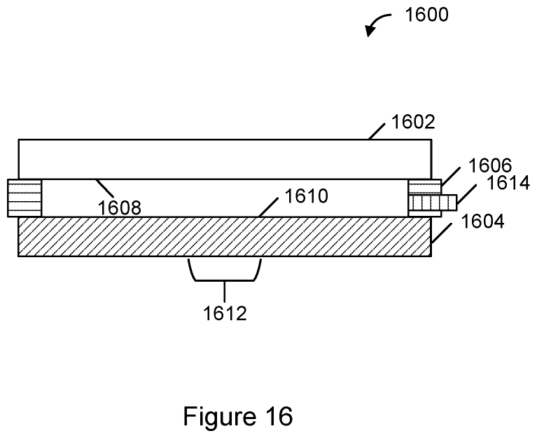

FIG. 16 illustrates an example wick-free vapor chamber 1600. In particular, FIG. 16 is a cross-sectional side view of wick-free vapor chamber 1600. As shown in FIG. 16, wick-free vapor chamber 1600 includes a wettability-patterned condenser 1602, a wettability-patterned evaporator 1604, and a spacer 1606. Wettability-patterned condenser 1602 and wettability-patterned evaporator 1604 are distinct parts of wick-free vapor chamber 1600. Each of wettability-patterned condenser 1602 and wettability-patterned evaporator 1604 are rectangular plates. For instance, wettability-patterned condenser 1602 and wettability-patterned evaporator 1604 can include copper plates. Alternatively, wettability-patterned condenser 1602 and wettability-patterned evaporator 1604 can include other metals and/or metal alloys. When assembled, spacer 1606 forms a vapor space between wettability-patterned condenser 1602 and wettability-patterned evaporator 1604. Spacer 1606 can include a rubber gasket, for instance, that facilitates sealing wick-free vapor chamber 1600. Use of spacer 1606 facilitates rapid replacement of wettability-patterned evaporator 1604 or wettability-patterned condenser 1602. However, the presence of spacer 1606 is not necessary. Rather than using spacer 1606, wettability-patterned condenser 1602 can be joined directly to wettability-patterned evaporator 1604.

Wettability-patterned condenser 1602 is configured to control condensation along patterned domains formed on a surface 1608 of wettability-patterned condenser. Surface 1608 of wettability-patterned condenser 1602 includes a pattern of wettable domains that promote filmwise condensation and non-wettable domains that promote dropwise condensation. By way of example, the patterned domains on surface 1608 can include wettable tracks that are configured to collect condensate at collection domains and return the condensate from the collection domains to patterned domains on a surface 1610 of wettability-patterned evaporator 1604. The collection domains can include superhydrophilic areas for bridging the condensate to wettability-patterned evaporator 1604. For instance, the collection domains can include circular end-wells. The non-wettable domains on surface 1608 can include hydrophobic areas that divide the patterned domains of wettability-patterned condenser 1602 into separate superhydrophilic areas having respective collection domains.

Wettability-patterned evaporator 1604, in turn, is configured to: i) accept condensate from wettability-patterned condenser 1602 and ii) transport the condensate along the patterned domains formed on surface 1610 to a hot domain portion 1612 of wettability-patterned evaporator 1604. Surface 1610 of wettability-patterned evaporator 1604 includes a pattern of wettable domains that transport the condensate that bridged across from wettability-patterned condenser 1602. The wettable domains can include wettable tracks that are configured to transport condensate to hot domain portion 1612.

In some examples, the patterned domains of wettability-patterned evaporator 1604 and the collection domains of wettability-patterned condenser 1602 substantially mate to facilitate a cyclical condensation process that transfers heat from wettability-patterned evaporator 1604 to wettability-patterned condenser 1602. For instance, the collection domains of wettability-patterned condenser 1602 can include superhydrophilic areas positioned for bridging the condensate to the patterned domains of wettability-patterned evaporator 1604.

Hot domain portion 1612 is a superhydrophilic circular area near a center of wettability-patterned evaporator 1604 that is configured to accumulate the condensate. In other examples, hot domain portion 1612 can be located in other positions. Hot domain portion 1612 can be positioned adjacent to a heat source, such that the heat source vaporizes the condensate accumulated at hot domain portion 1612. The size and/or shape of hot domain portion 1612 can vary based on the size and/or shape of the heat source that hot domain portion 1612 is intended to overlay.

In some instances, hot domain portion 1612 can include multiple hot domain portions, with each hot domain portion configured to contact a respective heat source of a system. When multiple hot domain portions are present, the patterned domains of wettability-patterned evaporator 1604 can be configured to transport the condensate to the multiple hot domain portions. Further, the non-wettable domains can include hydrophobic areas that divide the patterned domains into separate superhydrophilic areas having respective hot domain portions.

Wick-free vapor chamber 1600 also includes a tube 1614. Tube 1614 is inserted within spacer 1606. Tube 1614 is usable to evacuate wick-free vapor chamber 1600 (e.g., using a vacuum pump). In some examples, tube 1614 is also used to supply a liquid to the vapor space formed between wettability-patterned condenser 1602 and wettability-patterned evaporator 1604. Alternatively, a separate tube that is also inserted through spacer 1606 can be used to supply a liquid to the vapor space. The liquid can vary depending on the desired implementation. Generally, the liquid can include any phase-changing liquid. For instance, the liquid can include water, ethylene glycol, a hydrocarbon, an oil, ammonia, a solvent, alcohol, a refrigerant, or a dielectric fluid.

The dimensions of wick-free vapor chamber 1600 can vary depending on the desired implementation. For instance, the lateral extent of wick-free vapor chamber 1600 can vary from a few millimeters (e.g. 50 mm×50 mm) to a few meters (e.g., 1 m×2 m). The interspacing between surface 1608 of wettability-patterned condenser 1602 and surface 1610 of wettability-patterned evaporator 1604 can vary from a fraction of a millimeter (e.g., 0.5 mm) to approximately one centimeter.

In some examples, wettability-patterned evaporator 1604 of wick-free vapor chamber 1600 is operably connected to a heat source of a system. For instance, the heat source can include an electronic device, such as a battery charger or a graphics processing unit. With this arrangement, wick-free vapor chamber 1600 is configured to transfer heat from the heat source to wettability-patterned condenser 1602 of wick-free vapor chamber 1600.

In other examples, the orientation of wick-free vapor chamber 1600 with respect to the heat source can be reversed. As an example, wettability-patterned condenser 1602 of wick-free vapor chamber 1600 can be operably connected to a heat source of a system. For instance, the heat source can include the sun or a fire, and wick-free vapor chamber 1600 can be an integrated component of a construction building material. With this arrangement, wick-free vapor chamber 1600 is configured to hinder heat transfer from the heat source to wettability-patterned evaporator 1604 of wick-free vapor chamber 1600. Wick-free vapor chamber 1600 can also block undesirable heat backflow while working as a thermal diode. For instance, when wettability-patterned evaporator 1604 is operably connected to a heat source, wick-free vapor chamber 1600 can hinder heat transfer from wettability-patterned condenser 1602 to the heat source.

As such, wick-free vapor chamber 1600 is usable in a variety of thermal management systems, such as a thermal management system of a device or system in aerospace, spacecraft, construction building materials, electronics protection, electronics packaging, refrigeration, thermal control during energy harvesting, thermal isolation, solar devices, electronic vehicles, electric aircraft, and optoelectronics. The heat output by the heat source can range from a fraction of 1 W/cm² to hundreds of W/cm².

Although wick-free vapor chamber 1600 is shown as having a rectangular shape, the example is not meant to be limiting. In some instances, the heat source with which wick-free vapor chamber 1600 is desired to operate may include a curved surface. Accordingly, wettability-patterned condenser 1602 and wettability-patterned evaporator 1604 may be curved such that wick-free vapor chamber 1600 conforms to the curved surface of the heat source (not shown). Further, wick-free vapor chamber 1600 is operable in normal gravity environments, reduced gravity environments, and gravity-free environments.

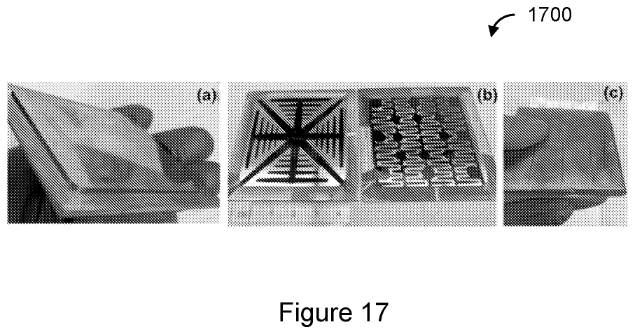

FIG. 17 depicts another example wick-free vapor chamber 1700. More specifically, FIG. 17 includes images of wick-free vapor chamber 1700 during various stages of fabrication.

A first image (a) shows a copper plate after initial machining. The copper plate can act as a condenser or an evaporator depending on the subsequent wettability pattern that is applied to a surface of the copper plate. A second image (b) shows a wettability-patterned evaporator (left-hand side) and a wettability-patterned condenser (right-hand side) when wick-free vapor chamber 1700 is unassembled. A third image (c) shows wick-free vapor chamber 1700 when assembled.

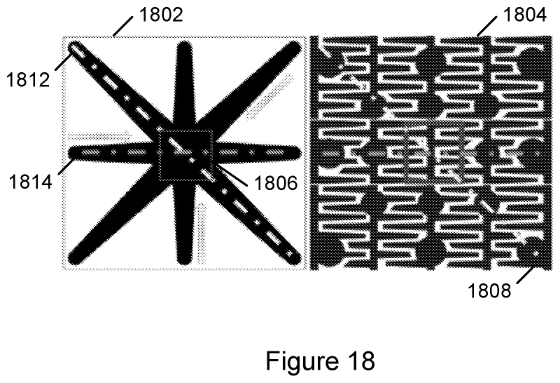

FIG. 18 illustrates an example combination of wettability patterns. The combination includes a wettability pattern 1802 and a wettability pattern 1804. Wettability pattern 1802 is an example of a wettability pattern that can be provided on an evaporator, such as wettability-patterned evaporator 1604 of FIG. 16. Wettability pattern 1804 is an example a wettability pattern that can be provided on a condenser, such as wettability-patterned condenser 1602 of FIG. 16. The designs of wettability pattern 1802 and wettability pattern 1804 feature wettable domains (shown in black) and non-wettable domains (shown in white).

Wettability pattern 1802 allows for the collection/accumulation and the transport of the returning condensate liquid to a hot domain portion 1806 (intended to overlay a heat source) where evaporation is strongest. For reference, an outline of hot domain portion 1806 is also shown overlaying wettability pattern 1804.

Wettability pattern 1804 allows spatially controlled dropwise and filmwise condensation and offers a way to move the condensate through specifically-built wedge tracks utilizing capillary forces. Wettability pattern 1804 includes circular end-wells 1808.

Wettability pattern 1802 and wettability pattern 1804 substantially mate to facilitate a cyclical condensation process. A diagonal dashed line is shown overlaying wettability pattern 1802 and wettability pattern 1804 to demonstrate that some of the end-wells 1808 of wettability pattern 1804 overlay a diagonal patterned track 1812 of wettability pattern 1802 when the combination of wettability patterns is utilized in a wick-free vapor chamber. A horizontal dashed line is also shown overlaying wettability pattern 1802 and wettability pattern 1804 to demonstrate that some of the end-wells 1808 of wettability pattern 1804 overlay a horizontal patterned track 1814 of wettability pattern 1804 when the combination of wettability patterns is utilized in a wick-free vapor chamber.

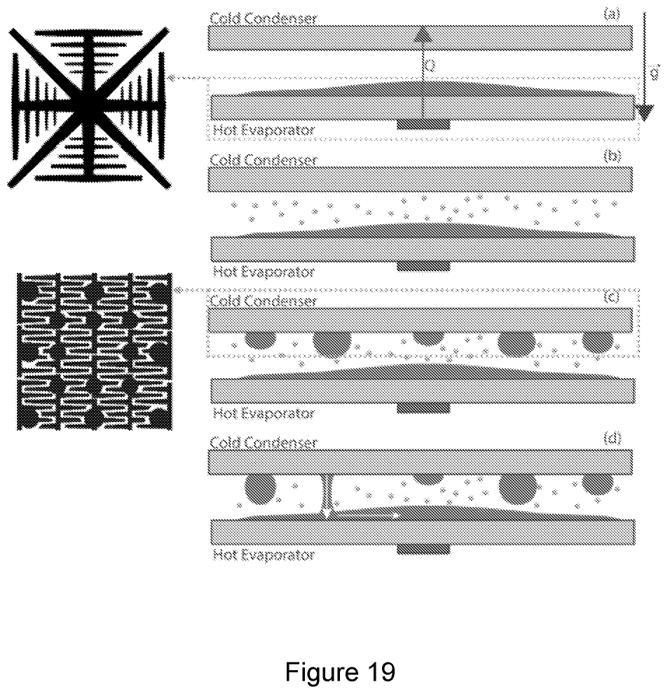

FIG. 19 illustrates the working principle of an example wick-free vapor chamber. Before the operation starts, the greater portion of the liquid fills/pools the evaporator side of the device (diagram (a)). While the wick-free vapor chamber operates, the working medium evaporates from the heated superhydrophilic central point of the evaporator and condenses on the opposing cold condenser (diagram (b)). On the condenser side, the condensed liquid is accumulated/gathered on strategically located superhydrophilic endpoints and bulges start forming. As more condensate is collected, the bulges grow (diagram (c)). When the bulges grow enough, the bulges eventually bridge the narrow gap between the two sides, forming a capillary bridge that allows the condensate to return to the hot side of the device where the Laplace pressure is lower (diagram (d)).

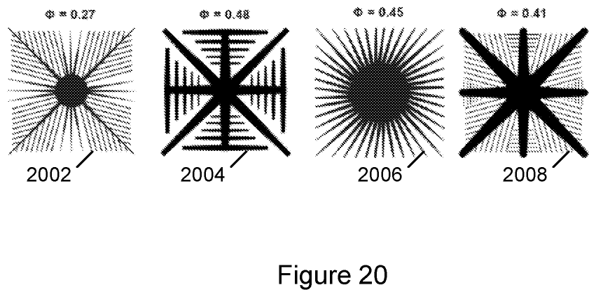

FIG. 20 illustrates additional example wettability patterns. In particular, FIG. 20 shows a first wettability pattern 2002, a second wettability pattern 2004, a third wettability pattern 2006, and a fourth wettability pattern 2008 that can be provided on a wettability-patterned evaporator, such as wettability-patterned evaporator 1604 of FIG. 16.

Superhydrophilic areas are shown in black in FIG. 20, and hydrophobic areas are shown in white. The superhydrophilic areas are designed in a way that serves the purposes of the working principle of the device, meaning to select and guide all the returning condensate from the condenser to the center of the evaporator. Each of the wettability patterns has a different ratio of wettable domains to non-wettable domains, as evident by values of the parameter Φ ranging from 0.27 for first wettability pattern 2002 and 0.48 for second wettability pattern 2004.

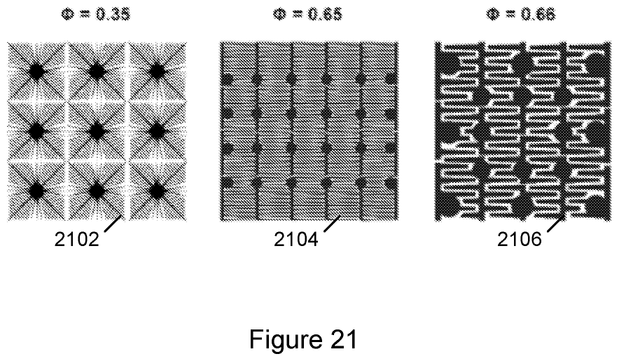

FIG. 21 illustrates additional example wettability patterns. In particular, FIG. 21 shows a first wettability pattern 2102, a second wettability pattern 2104, and a third wettability pattern 2106 that can be provided on a wettability-patterned condenser, such as wettability-patterned condenser 1602 of FIG. 16 or any of the wettability-patterned condensers described herein.

Superhydrophilic areas are shown in black in FIG. 21, and hydrophobic areas are shown in white. The superhydrophilic areas enhance condensate nucleation and result in FWC. The hydrophobic areas promote DWC. Each of the wettability patterns has a different ratio of wettable domains to non-wettable domains, as evident by the values of the parameter Φ ranging from 0.35 for first wettability pattern 2102 and 0.66 for third wettability pattern 2106. The designs of the wettability patterns shown in FIG. 21 facilitate an even and symmetric spread of condensed vapor on the cold surface of a condenser.

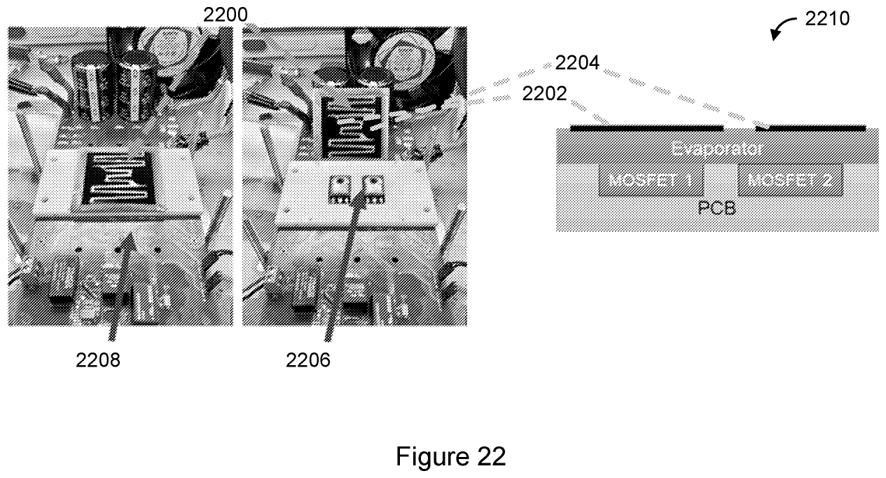

FIG. 22 illustrates an example wettability-patterned evaporator 2200. Wettability-patterned evaporator 2200 includes a first hot domain portion 2202 and a second hot domain portion 2204. As such, wettability-patterned evaporator 2200 is intended to accommodate heat input from two different heat sources provided beneath wettability-patterned evaporator.

In FIG. 22, the two different heat sources are metal-oxide-semiconductor field-effect transistors (MOSFETs) 2206 provided on a printed circuit board 2208. In the left image of FIG. 22, an example placement of wettability-patterned evaporator 2200 is shown. Wettability-patterned evaporator 2200 overlays MOSFETs 2206. In the right image of FIG. 22, wettability-patterned evaporator 2200 is removed such that MOSFETs 2206 are visible. As indicated in the right image of FIG. 22, and the cross-sectional view 2210 of the placement in the left image, first hot domain portion 2202 is intended to overlay a first MOSFET and second hot domain portion 2204 is intended to overlay a second MOSFET. With this arrangement, when wettability-patterned evaporator 2200 is provided within a wick-free vapor chamber, the wick-free vapor chamber can simultaneously and effectively transfer heat away from each of the MOSFETs.

### B. Example Fabrication Techniques and Device Characteristics

Wick-free vapor chambers have multiple different features. Experiments were performed to test the properties of wick-free vapor chambers. The following experimental vapor chambers and experimental results are provided as non-limiting examples of designs and features of wick-free vapor chambers.

### a. Fabrication Techniques

A wick-free vapor chamber was created featuring three distinct parts: a gasket, a wickless evaporator (copper plate), and a wickless condenser (copper plate). The evaporator and the condenser of the device can be described as wickless components of the device, especially for the fabrication method followed to create them. The same method was applied to both, pushing the time needed to create a device to a significant record low.

First, on a 63.5 mm×63.5 mm×2.0 mm copper plate (110 mirror-finish copper McMaster-Carr), a 50.8 mm×50.8 mm×1 mm protuberance was created by milling out a 6.35 mm wide and 1 mm deep square at the edges of the plate, on its mirror-finish side. On the other side of the plate three equidistant (15.9 mm apart) 32 mm long thermocouple grooves were machined. Subsequently, the samples were successively cleaned with soap water, DI water, ethanol, acetone, ethanol, DI water and finally dried out by compressed nitrogen.

To functionalize and make hydrophobic the mirror-finish side of the plate Teflon AF (Chemours AF 2400, 1%) was spin coated at 2000 RPM for 20 s. The curing procedure took place inside a single-zone tube furnace (Lindberg, Blue-M-HTF55322c) with a ramp rate of 20° C./min. The cure process was conducted under reducing atmosphere to avoid oxidation, which would have decreased the thermal conductivity of the copper, and to improve the adhesion and conformity of the coating on the treated surface. The 3-steps procedure was the following: (i) reach the solvent's boiling point (160° C. for 10 min), (ii) reach the polymer's glass transition temperature (240° C. for 5 min) and (iii) reach the adhesion-promoting temperature (330° C. for 15 min). The result of this process was a uniform and hydrophobic surface with sessile contact angle equal to 118.0°±1.0°.

Consequently, a 40% power YB fiber laser (Tykma Electrox, 20 W), 20 kHz pulse frequency, 200 mm/s rastering speed with 0.02 mm spacing along rastering lines, was used to pattern the surface by selectively etching away part of the coating and subtly textured the underlying metal surface. The laser-processed sample was then immersed in an aqueous solution of 2.5 mol/L of sodium hydroxide (Sigma-Aldrich, 50% H₂O) and 0.1 mol/L of ammonium persulfate (Sigma-Aldrich, ACS, 98%) at room temperature for 5 minutes. During this immersion process only the laser-treated domains were nanostructured by the creation of copper hydroxide, whereas the Teflon-coated mirror-finish areas stayed unchanged. The nanotextured areas were superhydrophilic with a contact angle of ˜0° and passivated, remaining superhydrophilic during the experiments.

The effective surface area of the exemplary vapor chamber was 50.8 mm×50.8 mm, and the working vapor space was 50.8 mm×50.8 mm×1 mm. The surrounding rim area was occupied by a 3.175 mm thick gasket (Viton® fluor elastomer rubber sheet, McMaster-Carr). The use of the gasket allows vapor chamber sealing for the span of each experimental run to conduct recurrent experiments under various operating conditions. This allowed the device to be disassembled and reassembled in a simple and resource-efficient manner, enabling continuous and repeated testing.

A Keyence Microscope was utilized to analyze the surface profiles of the evaporator and the condenser. The surface measurements showcased a characteristic of the surfaces. The ˜4.5 μm height difference between wettable domains and non-wettable domains and the average height of the micro-features ˜7.3 μm demonstrate the fact that the device is fully wickless. Metal wicks were not utilized, and neither were any other wicking features (i.e., micro-pillars); the device relies only on wettability patterning.

The experimental setup included various components. To ensure proper sealing of the device and effective thermal contact with all elements, several layers were held between two metal plates secured by four cylindrical posts. A Teflon block (8735K67 McMaster-Carr) with dimensions 73.2 mm×73.2 mm×15 mm was used to insulate the upper part of the cold plate and minimize thermal losses to the surroundings and a second Teflon block (8735K67 McMaster-Carr) with dimensions 73.2 mm×73.2 mm×50 mm was used to house the heater. On the top side of the vapor chamber, a liquid-cooled plate was placed (TETechnology, LCSSX1) to remove heat in a controlled manner. The wick-free vapor chamber was placed on top of a resistive heater (Component General, CPR-375-1) with dimensions 9.525 mm×9.525 mm×1.016 mm. The geometric centers of the vapor chamber, the heater and the Teflon blocks were aligned. The aim of this arrangement was to promote heat flow from the heater only to the vapor chamber and in the most uniform manner. A thin layer of paste (Omegatherm 201, Omega) was applied between the heater and the vapor chamber and between the device and the cold plate, to minimize contact resistance and the consequent loses.

The output of the heater was controlled by a voltage regulation system, a DC-power supply (Volteq HY10010EX) and an ammeter (Adafruit Industries LLC, Ammeter 0-9.99A) was connected to the circuit for accurate reading of the current via the heater. The temperature measurement system involved eight thermocouples (Omega, T-type, bead diameter 0.13 mm), two of them on the inlet and outlet of the cold plate, three of them in the thermocouple grooves of the evaporator and the last three on the condenser respectively positioned. The temperature data were stored in a PC utilizing a data acquisition system (Omega DAQ, USB 2400 series) at a sampling frequency of 1 Hz for the collection.

The working medium (DI water—degassed for 2 hours) was supplied using an on-off valve and a syringe. A 1.6 mm diameter through-hole was drilled on one side of the gasket, perpendicular to the grooves, and a 25.4 mm long copper tube (122 copper tube, 0.4 mm wall thickness, 1.6 mm OD, McMaster-Carr) was fitted and used to fill the device after the initial evacuation. The cooling system connect with the cold plate included a chiller (Neslab RTE-110) set at 20° C., providing to the cold plate pure ethylene glycol (Alfa Aesar, Ethylene Glycol 99%) with a flow rate of 0.112 kg/s. The vacuuming system included a vacuum pump (Alcatel Annecy 2008A) which evacuated the vapor chamber from air and non-condensable gasses and was connected to one on-off valve, one flow-adjusting valve, and a vacuum gauge connected in series.

### b. Thermal Resistance

The efficiency of the apparatus was calculated using the overall thermal resistance Rₜₒₜ as follows:

$${R}_{t o t} = \frac{{T}_{h o t} - {T}_{cold}^{a v g}}{{Q}_{i n}}$$

where Qᵢₙ is the heat supply, Tₕₒₜ is the temperature between the heater and the evaporator, and T^{avg}_{cold} is the average temperature of the condenser plate.

To start an experimental run the vapor chamber was allowed to reach thermal equilibrium with the cold plate (˜20° C.) before the heater was powered on. As mentioned above the resistive heater output is controlled by the voltage regulator. Each experiment starts at 10 V and the voltage increased stepwise by 5 V increments, until the device reaches a thermal runaway. Each time the voltage is increased to a certain point, the system is needed to reach a steady state before the next step up. Throughout tests, it was found that only 1 minute was enough for the vapor chamber to reach a steady state. Qin was held constant for 2.5 minutes in all, and the last 30 seconds in steady state were used as output data to calculate the performance of the device. All experiments were replicated 3 times.

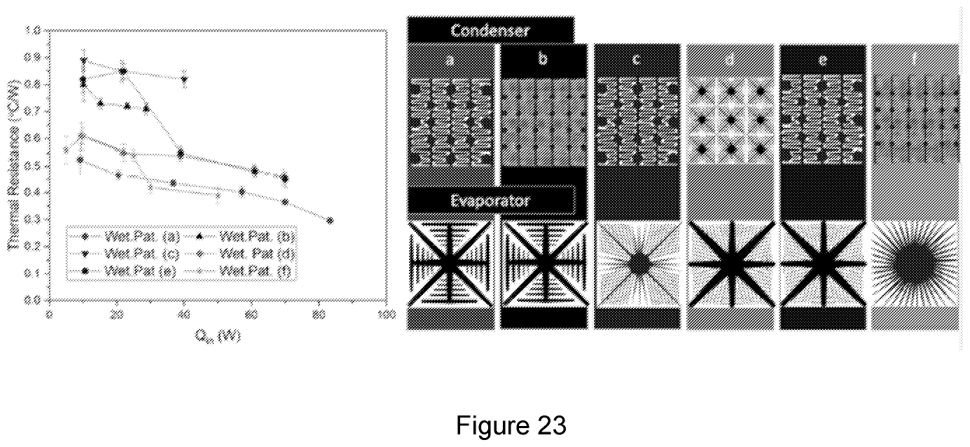

FIG. 23 illustrates the performance of various wick-free vapor chambers. In particular, FIG. 23 shows the performance of six devices with the same dimensions but different wettability-pattern designs. For each device, more experiments took place to find the best CR for each one of them. On the graph on the left side of FIG. 23, only the best performing CR is demonstrated. Each of the six devices had different values of CR. All the experiments stopped when each device reached a thermal runaway.

The left-hand side of FIG. 23 illustrates the thermal resistances of the six different devices plotted against heat. The worst-performing device featured the combination of wettability-patterns denoted with the letter (c) and downward-pointing triangle line markers. The worst-performing device outperformed three control devices that were wickless but un-patterned.

The best-performing device featured the combination of wettability patterns denoted with the letter (a) and circle line markers was able to handle the most heat without going to a thermal runaway. It also featured the lowest thermal resistance at most of the heat levels. This device has a 0.28 K/W thermal resistance at 85 W. As shown in FIG. 23, the wettability pattern for the evaporator resembled a complex star, and the wettability pattern for the condenser featured 16 end-wells positioned to be distributed over the star legs.

The best-performing combination (letter (a)) was selected for further testing. New devices were made, and their performance was evaluated. A new device with the same set of patterns, same, same vapor-space height but thinner by 1 mm was created and evaluated further. The new width makes the device 20% thinner than the previous one because, the thinner device comprised of two copper plates half a millimeter thinner than the previous one.

The performance of the vapor chamber with four distinct water charging ratios equal to 5%, 17%, 20% and 27% was quantified. The device thickness was 4 mm with a vapor space gap of 1 mm. The device with CR=20% outperformed the other three especially at heat input less than 117W. This CR demonstrated lowest thermal resistance R=0.18±0.035 K/W at Qᵢₙ=9.7 W. At the maximum heat input, the device with CR=17% outperforms the other two with 0.26 K/W at 196W, meaning a 10% higher performance.

These results establish the potential of wettability patterns replacing all metal wicks of vapor chambers in accordance with the principles herein. This technique is also scalable, due to the moderate size and light weight of the apparatus, the simple and straightforward fabrication method, and the durable and commonly used materials.

### c. Thermal Diodicity

The wick-free vapor chambers disclosed herein are also capable of functioning as thermal diodes. To demonstrate this feature, wick-free vapor chambers were tested as a thermal diode. In particular, a first wick-free vapor chamber having the combination of wettability patterns denoted as letter (b) in FIG. 23 was fabricated, and a second wick-free vapor chamber having the combination of wettability patterns denoted as letter (a) in FIG. 23 was fabricated. The working vapor space was 50.8 mm×50.8 mm×1 mm. An experimental procedure similar to the procedure outlined above with respect to the thermal diodicity of the hybrid vapor chamber was carried out.

Thermal resistance in the forward mode was first evaluated for the first and second wick-free vapor chambers. The second wick-free vapor chamber outperformed the first wick-free vapor chamber for the entire test range. So, the second wick-free vapor chamber was selected for further analysis with respect to thermal diodicity.

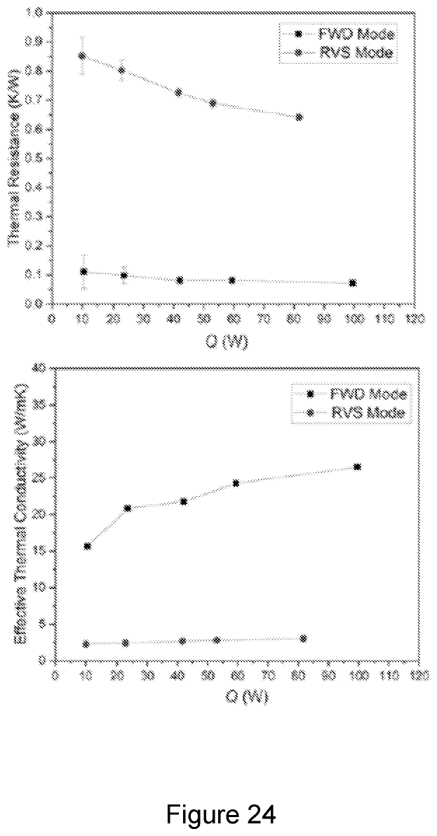

FIG. 24 plots the thermal performance of a wick-free vapor chamber, namely, the wick-free vapor chamber having the combination of wettability patterns denoted as letter (a) in FIG. 23. The top graph of FIG. 24 demonstrates the total thermal resistance of the wick-free vapor chamber, while the bottom graph shows the effective thermal conductivity, with respect to the heat input for both cases.

The curves shown in FIG. 24 demonstrate the thermal performance of the same wick-free vapor chamber during two different modes of operation: the curves with the squares demonstrate the performance in the FWD mode, while the curves with the dots demonstrate the performance in the RVS mode. As it has been already stated, in the FWD mode the system performs as a vapor chamber, meaning that low thermal resistance is expected. For example, at 99.5 W the thermal resistance is 0.07±0.01 K/W. On the RVS mode, the system performs as a thermal barrier and shows the worst-performing thermal resistance at 10.1 W, equal to 0.85±0.05 K/W, 89% worse than in the FWD mode at the same Qin. Furthermore, the same trend is demonstrated for the thermal conductivity as well, the best performance in the FWD mode is 26.51±0.09 W/m−K. The average conductivity in the FWD mode was 21.96 W/m−K, a value ten-fold higher than the RVS mode, which had 2.65 W/m−K.

The data presented so far has established that the apparatus performs in a different way in the two modes of operation. A wettability patterned biphilic condenser is superior to a superhydrophobic one for the following reasons:

(i) The condensate can be mustered in specific points and from there can be transported back to the evaporator, instead of the randomness of the return-spots of the jumping droplets. This suggests that a superhydrophobic condenser cannot be coupled with a wettability patterned evaporator.

(ii) The wettability-patterned condensers are proven to not lose their ability to operate in all conditions (pressure, saturation, temperature).

(iii) The wettability-patterned condensers are proven to endure weeks of testing with limited degradation, while surfaces that are comprised of vulnerable nanostructures needed for a superhydrophobic surface can be damaged and eventually cease to work.

The second wick-free vapor chamber, featuring the combination of wettability patterns denoted as letter (a) in FIG. 23, showed a diodicity y as high as 9. This value demonstrates the system's ability to effectively remove the heat from a heat source (i.e., electronic chip) while, in parallel, protecting it from damage by excessive heat backflow. The diodicity of the diode is ascribed to the different wettability-pattern designs on the two copper plates comprising the system. On the forward mode, the two patterns work as designed to enable heat transfer, but on the reverse mode, the patterns no longer function harmoniously with each other, and the heat transfer is hindered. The simplicity of the design and its moderate dimensions are advantages that make this thermal management component attractive for engineering applications.

### IV. Example Methods

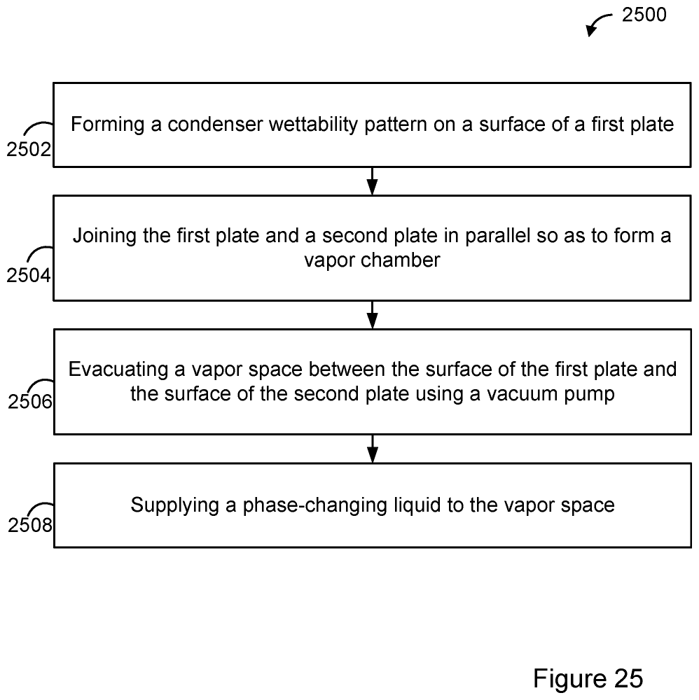

FIG. 25 is a flow chart of an example method 2500. Method 2500 can, for example, be used to fabricate a hybrid vapor chamber. As shown in FIG. 25, at block 2502, method 2500 includes forming a condenser wettability pattern on a first plate. At block 2504, method 2500 includes joining the first plate and a second plate in parallel so as to form a vapor chamber. At block 2506, method 2500 includes evacuating a vapor space between the surface of the first plate and the surface of the second plate using a vacuum pump. And at block 2508, method 2500 includes supplying a phase-changing liquid to the vapor space.

The condenser wettability pattern can include a pattern of wettable domains that promote filmwise condensation and non-wettable domains that promote dropwise condensation. Forming the condenser wettability pattern can include: i) coating the surface of the first plate with a low-surface-energy material; ii) etching a pattern on the coated surface of the first plate; and iii) treating etched regions of the coated surface so as to create a biphilic surface.

In some examples, method 2500 also includes coupling the vapor chamber to a heat source.

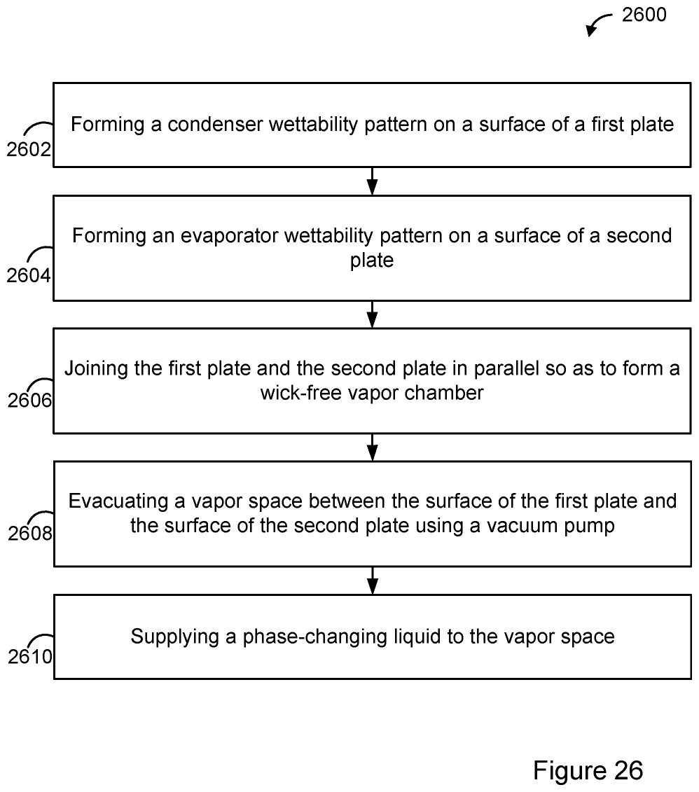

FIG. 26 is a flow chart of an example method 2600. Method 2600 can, for example, be used to fabricate a wick-free vapor chamber. As shown in FIG. 26, at block 2602, method 2600 includes forming a condenser wettability pattern on a first plate. At block 2604, method 2600 includes forming an evaporator wettability pattern on a second plate. At block 2606, method 2600 includes joining the first plate and the second plate in parallel so as to form a vapor chamber. At block 2608, method 2600 includes evacuating a vapor space between the surface of the first plate and the surface of the second plate using a vacuum pump. And at block 2610, method 2600 includes supplying a phase-changing liquid to the vapor space.

The condenser wettability pattern can include a pattern of wettable domains that promote filmwise condensation and non-wettable domains that promote dropwise condensation. Similarly, the evaporator wettability pattern can include a pattern of wettable domains that promote transport of the condensate to a hot domain portion, where the condensate can then evaporate and cool the area locally. In some examples, the condenser wettability pattern and the evaporator wettability pattern substantially mate to facilitate a cyclical condensation process that transfer heat from the second plate to the first plate.

Forming the condenser wettability pattern can include: i) coating the surface of the first plate with a low-surface-energy material; ii) etching a pattern on the coated surface of the first plate; and iii) treating etched regions of the coated surface so as to create a biphilic surface. Similarly, forming the evaporator wettability pattern can include: i) coating the surface of the second plate with a low-surface-energy material; ii) etching a pattern on the coated surface of the second plate; and iii) treating etched regions of the coated surface so as to create a biphilic surface.

In some examples, method 2600 also includes coupling the vapor chamber to a heat source.

### V. Additional Example Embodiments

The following clauses are offered as further description of the disclosed embodiments.

(1) A wick-free vapor chamber comprising:

a wettability-patterned condenser configured to control vapor condensation along patterned domains formed on the wettability-patterned condenser; and

a wettability-patterned evaporator configured to: i) accept condensate from the wettability-patterned condenser and ii) transport the condensate along patterned domains formed on the wettability-patterned evaporator to a hot domain portion of the wettability-patterned evaporator.

(2) The wick-free vapor chamber of clause (1), wherein the patterned domains of the wettability-patterned condenser are configured to collect the condensate at collection domains and return the condensate from the collection domains to the patterned domains of the wettability-patterned evaporator.

(3) The wick-free vapor chamber of clause (2), wherein the patterned domains of the wettability-patterned evaporator and the collection domains of the wettability-patterned condenser substantially mate to facilitate a cyclical condensation process that transfers heat from the wettability-patterned evaporator to the wettability-patterned condenser.

(4) The wick-free vapor chamber of clause (3), wherein the collection domains of the wettability-patterned condenser are superhydrophilic areas positioned for bridging the condensate to the patterned domains of the wettability-patterned evaporator.

(5) The wick-free vapor chamber of clause (4), wherein the collection domains of the wettability-patterned condenser comprise circular end-wells.

(6) The wick-free vapor chamber of clause (1), wherein the surface of the wettability-patterned condenser comprises a pattern of wettable domains that promote filmwise condensation and non-wettable domains that promote dropwise condensation.

(7) The wick-free vapor chamber of clause (6), wherein the non-wettable domains comprise hydrophobic areas that divide the patterned domains of the wettability-patterned condenser into separate superhydrophilic areas having respective collection domains.

(8) The wick-free vapor chamber of clause (1), wherein the surface of the wettability-patterned evaporator comprises a pattern of wettable domains and non-wettable domains that is configured to transport the condensate to the hot domain portion.

(9) The wick-free vapor chamber of clause (1), wherein the hot domain portion of the wettability-patterned evaporator comprises a superhydrophilic area that is configured to accumulate the condensate.

(10) The wick-free vapor chamber of clause (1), wherein the patterned domains of the wettability-patterned evaporator are configured to transport the condensate to multiple hot domain portions of the wettability-patterned evaporator.

(11) The wick-free vapor chamber of clause (10), wherein the wettability-patterned evaporator comprises hydrophobic areas that divide the patterned domains into separate superhydrophilic areas laid to address respective hot domain portions.

(12) The wick-free vapor chamber of clause (1), wherein the hot domain portion is a portion of the wettability-patterned evaporator that is configured to overlay a heat source.

(13) The wick-free vapor chamber of clause (1), wherein the wick-free vapor chamber is configured to operate as a thermal diode by:

enabling heat transfer from the wettability-patterned evaporator to the wettability-patterned condenser, and

hindering heat transfer in the opposite direction.

(14) The wick-free vapor chamber of clause (1), further comprising a spacer positioned between the wettability-patterned evaporator and the wettability-patterned condenser.

(15) The wick-free vapor chamber of clause (14), wherein an interspacing between the wettability-patterned evaporator and the wettability-patterned condenser is less than one millimeter.

(16) The wick-free vapor chamber of clause (1), configured to evaporate and condense a liquid selected from the group consisting of water, ethylene glycol, a hydrocarbon, an oil, ammonia, a solvent, alcohol, a refrigerant, and a dielectric fluid.

(17) A system comprising:

a heat source; and

a wick-free vapor chamber operably connected to the heat source, the wick-free vapor chamber comprising:

a wettability-patterned condenser configured to control vapor condensation along patterned domains formed on the wettability-patterned condenser; and

a wettability-patterned evaporator configured to: i) accept condensate from the wettability-patterned condenser and ii) transport the condensate along patterned domains formed on the wettability-patterned evaporator to a hot domain portion of the wettability-patterned evaporator.

(18) The system of clause (17), wherein:

the wettability-patterned evaporator is operably connected to the heat source, and

the wick-free vapor chamber is configured to transfer heat from the heat source to the wettability-patterned condenser.

(19) The system of clause (17), wherein:

a condenser side of the wick-free vapor chamber is operably connected to the heat source, and

the wick-free vapor chamber is configured to hinder heat transfer away from the heat source to the other side of the wick-free vapor chamber.

(20) The system of clause (17), wherein the surface of the wettability-patterned condenser comprises a pattern of wettable domains that promote filmwise condensation and non-wettable domains that promote dropwise condensation.

(21) The system of clause (17), wherein the surface of the wettability-patterned evaporator comprises a pattern of wettable domains and non-wettable domains that is configured to transport the condensate to the hot domain portion.

(22) The system of clause (17), wherein:

the heat source comprises a curved surface, and

wettability-patterned condenser and the wettability-patterned evaporator are curved such that the wick-free vapor chamber conforms to the curved surface of the heat source.

(23) The system of clause (17), wherein the heat source comprises an electronic device.

(24) The system of clause (17), wherein the system comprises a thermal management system.

(25) The system of clause (17), wherein the wick-free vapor chamber is an integrated component of a construction building material.

(26) A method comprising:

forming a condenser wettability pattern on a first plate;

forming an evaporator wettability pattern on a second plate;

joining the first plate and the second plate in parallel so as to form a wick-free vapor chamber;

evacuating a vapor space between the surface of the first plate and the surface of the second plate using a vacuum pump; and

supplying a phase-changing liquid to the vapor space.

(27) The method of clause (26), further comprising coupling the wick-free vapor chamber to a heat source.

(28) The method of clause (26), wherein:

the condenser wettability pattern comprises a pattern of wettable domains that promote filmwise condensation and non-wettable domains that promote dropwise condensation, and

the evaporator wettability pattern comprises a pattern of wettable domains and non-wettable domains that is configured to transport the condensate to the hot domain portion.

(29) The method of clause (26), wherein the condenser wettability pattern and the evaporator wettability pattern substantially mate to facilitate a cyclical condensation process that transfers heat from the second plate to the first plate.

(30) The method of clause (26), wherein forming the condenser wettability pattern comprises:

coating the surface of the first plate with a low-surface-energy material;

etching a pattern on the coated surface of the first plate; and

treating etched regions of the coated surface so as to create a biphilic surface.

(31) The method of clause (26), wherein forming the evaporator wettability pattern comprises:

coating the surface of the first plate with a low-surface-energy material;

etching a pattern on the coated surface of the first plate; and

treating etched regions of the coated surface so as to create a biphilic surface.

(32) A wettability-patterned evaporator for a wick-free vapor chamber, the wettability-patterned evaporator comprising:

patterned domains formed on the wettability-patterned evaporator and configured to: i) accept condensate from a wettability-patterned condenser and ii) transport the condensate along the patterned domains to a hot domain portion of the wettability-patterned evaporator.

(33) The wettability-patterned evaporator of clause (32), wherein the surface of the wettability-patterned evaporator comprises a pattern of wettable domains and non-wettable domains that is configured to transport the condensate to the hot domain portion.

(34) The wettability-patterned evaporator of clause (32), wherein the hot domain portion of the wettability-patterned evaporator comprises a superhydrophilic area that is configured to accumulate the condensate.

(35) A vapor chamber comprising:

a wettability-patterned condenser configured to control vapor condensation along patterned domains formed on the wettability-patterned condenser; and

an evaporator configured to accept condensate from the wettability-patterned condenser.

(36) The vapor chamber of clause (35), wherein the patterned domains of the wettability-patterned condenser are configured to collect the condensate at collection domains and return the condensate from the collection domains to the evaporator.

(37) The vapor chamber of clause (36), wherein the evaporator comprises wicking posts that contact the collection domains.

(38) The vapor chamber of clause (36), wherein the collection domains of the wettability-patterned condenser are superhydrophilic areas for bridging the condensate to the evaporator.

(39) The vapor chamber of clause (38), wherein the wettability-patterned condenser and the evaporator are offset by a distance that is selected such that, as condensate bulges accumulate at the collection domains, the condensate bulges contact the evaporator.

(40) The vapor chamber of clause (36), wherein the collection domains of the wettability-patterned condenser comprise circular end-wells.

(41) The vapor chamber of clause (35), wherein the surface of the wettability-patterned condenser comprises a pattern of wettable domains that promote filmwise condensation and non-wettable domains that promote dropwise condensation.

(42) The vapor chamber of clause (41), wherein the non-wettable domains comprise hydrophobic areas that divide the patterned domains of the wettability-patterned condenser into separate superhydrophilic areas having respective collection domains.

(43) The vapor chamber of clause (35), wherein the vapor chamber is configured to operate as a thermal diode by:

enabling heat transfer from the evaporator to the wettability-patterned condenser, and

hindering heat transfer from the wettability-patterned condenser to the evaporator.

(44) The vapor chamber of clause (35), further comprising a spacer positioned between the evaporator and the wettability-patterned condenser.

(45) The vapor chamber of clause (35), wherein an interspacing between the evaporator and the wettability-patterned condenser is less than one millimeter.

(46) A system comprising:

a heat source; and

a vapor chamber operably connected to the heat source, the vapor chamber comprising:

a wettability-patterned condenser configured to control vapor condensation along patterned domains formed on the wettability-patterned condenser, and

an evaporator configured to accept condensate from the wettability-patterned condenser.

(47) The system of clause (46), wherein:

the evaporator is operably connected to the heat source, and

the chamber is configured to transfer heat from the heat source to the wettability-patterned condenser.

(48) The system of clause (46), wherein:

a condenser side of the vapor chamber is operably connected to the heat source, and

the vapor chamber is configured to hinder heat transfer away from the heat source to the other side of the wick-free vapor chamber.

(49) The system of clause (46), wherein the surface of the wettability-patterned condenser comprises a pattern of wettable domains that promote filmwise condensation and non-wettable domains that promote dropwise condensation.

(50) The system of clause (46), wherein:

the heat source comprises a curved surface, and

wettability-patterned condenser and the evaporator are curved such that the vapor chamber conforms to the curved surface of the heat source.

(51) The system of clause (46), wherein the heat source comprises an electronic device.

(52) The system of clause (46), wherein the system comprises a thermal management system.

(53) The system of clause (46), wherein the vapor chamber is an integrated component of a construction building material.

(54) A method comprising:

forming a condenser wettability pattern on a first plate;

joining the first plate and a second plate in parallel so as to form a vapor chamber;

evacuating a vapor space between the surface of the first plate and the second plate using a vacuum pump; and

supplying a phase-changing liquid to the vapor space.

(55) The method of clause (54), further comprising coupling the vapor chamber to a heat source.

(56) The method of clause (54), wherein the condenser wettability pattern comprises a pattern of wettable domains that promote filmwise condensation and non-wettable domains that promote dropwise condensation.

(57) The method of clause (54), wherein forming the condenser wettability pattern comprises:

coating the surface of the first plate with a low-surface-energy material;

etching a pattern on the coated surface of the first plate; and

treating etched regions of the coated surface so as to create a biphilic surface.

### VI. Example Variations

Although certain variations have been discussed in connection with one or more examples of this disclosure, these variations can also be applied to all of the other examples of this disclosure as well.

Although select examples of this disclosure have been described, alterations and permutations of these examples will be apparent to those of ordinary skill in the art. Other changes, substitutions, and/or alterations are also possible without departing from the invention in its broader aspects as set forth in the following claims.

1. A wick-free vapor chamber comprising:
a wettability-patterned condenser configured to control vapor condensation along patterned domains formed on the wettability-patterned condenser; and
a wettability-patterned evaporator configured to: i) accept condensate from the wettability-patterned condenser and ii) transport the condensate along patterned domains formed on the wettability-patterned evaporator to a hot domain portion of the wettability-patterned evaporator.

2. The wick-free vapor chamber of claim 1, wherein the patterned domains of the wettability-patterned condenser are configured to collect the condensate at collection domains and return the condensate from the collection domains to the patterned domains of the wettability-patterned evaporator.

3. The wick-free vapor chamber of claim 2, wherein the patterned domains of the wettability-patterned evaporator and the collection domains of the wettability-patterned condenser substantially mate to facilitate a cyclical condensation process that transfers heat from the wettability-patterned evaporator to the wettability-patterned condenser.

4. The wick-free vapor chamber of claim 3, wherein the collection domains of the wettability-patterned condenser are superhydrophilic areas positioned for bridging the condensate to the patterned domains of the wettability-patterned evaporator.

5. The wick-free vapor chamber of claim 4, wherein the collection domains of the wettability-patterned condenser comprise circular end-wells.

6. The wick-free vapor chamber of claim 1, wherein the surface of the wettability-patterned condenser comprises a pattern of wettable domains that promote filmwise condensation and non-wettable domains that promote dropwise condensation.

7. The wick-free vapor chamber of claim 6, wherein the non-wettable domains comprise hydrophobic areas that divide the patterned domains of the wettability-patterned condenser into separate superhydrophilic areas having respective collection domains.

8. The wick-free vapor chamber of claim 1, wherein the surface of the wettability-patterned evaporator comprises a pattern of wettable domains and non-wettable domains that is configured to transport the condensate to the hot domain portion.

9. The wick-free vapor chamber of claim 1, wherein the hot domain portion of the wettability-patterned evaporator comprises a superhydrophilic area that is configured to accumulate the condensate.

10. The wick-free vapor chamber of claim 1, wherein the patterned domains of the wettability-patterned evaporator are configured to transport the condensate to multiple hot domain portions of the wettability-patterned evaporator.

11. The wick-free vapor chamber of claim 10, wherein the wettability-patterned evaporator comprises hydrophobic areas that divide the patterned domains into separate superhydrophilic areas laid to address respective hot domain portions.

12. (canceled)

13. The wick-free vapor chamber of claim 1, wherein the wick-free vapor chamber is configured to operate as a thermal diode by:
enabling heat transfer from the wettability-patterned evaporator to the wettability-patterned condenser, and
hindering heat transfer in the opposite direction.

14. The wick-free vapor chamber of claim 1, further comprising a spacer positioned between the wettability-patterned evaporator and the wettability-patterned condenser.

15. The wick-free vapor chamber of claim 14, wherein an interspacing between the wettability-patterned evaporator and the wettability-patterned condenser is less than one millimeter.

16. (canceled)

17. A system comprising:
a heat source; and
a wick-free vapor chamber operably connected to the heat source, the wick-free vapor chamber comprising:
a wettability-patterned condenser configured to control vapor condensation along patterned domains formed on the wettability-patterned condenser; and
a wettability-patterned evaporator configured to: i) accept condensate from the wettability-patterned condenser and ii) transport the condensate along patterned domains formed on the wettability-patterned evaporator to a hot domain portion of the wettability-patterned evaporator.

18. (canceled)

19. (canceled)

20. (canceled)

21. (canceled)

22. (canceled)

23. (canceled)

24. (canceled)

25. (canceled)

26. A method comprising:
forming a condenser wettability pattern on a first plate;
forming an evaporator wettability pattern on a second plate;
joining the first plate and the second plate in parallel so as to form a wick-free vapor chamber;
evacuating a vapor space between the surface of the first plate and the surface of the second plate using a vacuum pump; and
supplying a phase-changing liquid to the vapor space.

27. (canceled)

28. The method of claim 26, wherein:
the condenser wettability pattern comprises a pattern of wettable domains that promote filmwise condensation and non-wettable domains that promote dropwise condensation, and
the evaporator wettability pattern comprises a pattern of wettable domains that promote transport of the condensate to the hot domain portion.

29. The method of claim 26, wherein the condenser wettability pattern and the evaporator wettability pattern substantially mate to facilitate a cyclical condensation process that transfers heat from the second plate to the first plate.

30. The method of claim 26, wherein forming the condenser wettability pattern comprises:
coating the surface of the first plate with a low-surface-energy material;
etching a pattern on the coated surface of the first plate; and
treating etched regions of the coated surface so as to create a biphilic surface.

31. The method of claim 26, wherein forming the evaporator wettability pattern comprises:
coating the surface of the second plate with a low-surface-energy material;
etching a pattern on the coated surface of the second plate; and
treating etched regions of the coated surface so as to create a biphilic surface.

32. (canceled)

33. (canceled)

34. (canceled)
